(19) United States
(12) Patent Application Publication
(10) Pub. No.: US 2026/0181814 A1
(43) Pub. Date: Jun. 25, 2026

(54) Thermalized Magnetic Shielding for Quantum Processing Units

(71) Applicant: Rigetti & Co, LLC, Berkeley, CA (US)

(72) Inventors: David Pappas, Boulder, CO (US); Rudy Pontemayor, Berkeley, CA (US); David Snow, Berkeley, CA (US)

(73) Assignee: Rigetti & Co, LLC, Berkeley, CA (US)

(21) Appl. No.: 19/314,391

(22) Filed: Aug. 29, 2025

Related U.S. Application Data
(63) Continuation of application No. PCT/US2024/018410, filed on Mar. 4, 2024.
(60) Provisional application No. 63/488,344, filed on Mar. 3, 2023.
(60) Provisional application No. 63/585,274, filed on Sep. 26, 2023.

(51) Int. Cl. H05K 7/20

(52) U.S. Cl. CPC H05K 7/20; H05K 7/2039; H05K 7/20518

(57) ABSTRACT

In a general aspect, an assembly is configured for thermalizing quantum circuits at low temperature and providing them shielding from magnetic fields and infrared radiation. In some implementations, an assembly to house a component of a quantum processing unit in a cryogenic environment, includes a plate, a magnetic shielding structure, a first thermalization pathway, and a second, independent thermalization pathway. The plate is configured to reside in thermal contact with a thermalization stage of a cryostat. The magnetic shielding structure defines an interior volume to contain a component of a quantum processing unit. The component resides on a circuit board. A first thermalization pathway provides thermal contact between the plate and the magnetic shielding structure. The second, independent thermalization pathway provides thermal contact between the plate and the circuit board.

### CROSS-REFERENCE TO RELATED APPLICATIONS

This application claims priority to U.S. Provisional Patent Application No. 63/488,344, filed Mar. 3, 2023, entitled “Thermalized Magnetic Shielding for Quantum Processing Units;” and to U.S. Provisional Patent Application No. 63/585,274, filed Sep. 26, 2023, entitled “Thermalized Magnetic Shielding for Quantum Processing Units.” The above-referenced priority documents are incorporated herein by reference in their entireties.

### TECHNICAL FIELD

The following description relates to thermalized magnetic shielding for quantum processing units.

### BACKGROUND

Quantum computers can perform computational tasks by storing and processing information within quantum states of quantum systems. For example, qubits (i.e., quantum bits) can be stored in and represented by an effective two-level sub-manifold of a quantum coherent physical system. A variety of physical systems have been proposed for quantum computing applications. Examples include superconducting circuits, trapped ions, spin systems and others.

### BRIEF DESCRIPTION OF THE DRAWINGS

FIG. 1 is a block diagram of an example computing environment.

FIG. 2 is a diagram showing aspects of an example cryostat in a quantum computing system.

FIGS. 3A-3D include diagrams showing a perspective view, an exploded view, a first cross-sectional view, and a second cross-sectional view of an example apparatus.

FIG. 4A is a plot showing the thermal conductivity in watts per meter per Kelvin (W/m·K) of a magnetic shielding can with and without a thermalization surface treatment as a function of temperature in K.

FIG. 4B is a semi-log plot showing the temperature in Kelvin of the magnetic shielding can with and without the thermalization treatment as a function of time during a simulated cooling process.

FIG. 4C is a plot showing the temperature of a circuit board in the magnetic shielding can with the thermalization surface treatment as a function of time during the simulated cooling process.

FIG. 5 is a semi-log plot showing the magnetic field strength in Tesla (T) as a function of distance from the center of the magnetic shielding cans in inches (in).

FIGS. 6A-6B include diagrams showing perspective views of an example apparatus.

FIG. 7 is a plot showing the temperature of a QPU puck in the example apparatus as a function of time during a simulated cooling process.

FIGS. 8A-8B include diagrams showing aspects of the apparatus of FIGS. 6A-6B residing in an example cryostat of a quantum computing system.

FIGS. 9A-9B include diagrams showing perspective views of an example apparatus.

FIGS. 10A-10B include diagrams showing aspects of the apparatus of FIGS. 9A-9B residing in an example cryostat of a quantum computing system.

### DETAILED DESCRIPTION

In some aspects, methods, systems, and apparatuses for improving the performance of a quantum processing unit are disclosed. Quantum elements of quantum processing units (e.g., Josephson junctions in superconducting qubits, individual electrons in spin qubits, etc.) are sensitive to external electromagnetic interference, which can cause errors and decoherence in quantum states. In some instances, magnetic shielding made of materials that have high magnetic permeability can be used to absorb and dissipate undesired magnetic energy, which can prevent some or all of the unwanted magnetic energy from reaching the quantum processing units. In some instances, a magnetic shielding structure can be configured to enclose a component of a quantum processing unit to create a low-field region around the enclosed component. In some instances, components of the magnetic shielding structure can be surface treated to improve their thermal conductivity. The magnetic shielding structure can be effectively thermalized to a thermalization stage in a cryostat (e.g., the lowest-temperature thermalization stage where the quantum processing unit is also thermalized to) and cooled to cryogenic temperatures so that it can uniformly absorb magnetic fields without generating significant temperature fluctuation and thus thermal noise to the enclosed quantum processing unit, and without acting as a thermal bottleneck limiting the overall cooling performance of the system.

In some instances, the apparatuses can further allow communication of ultra-high-density RF and DC signals from outside of the thermalized magnetic shielding structure to the component of the quantum processing unit residing inside of the magnetic shielding structure. In some instances, the methods and apparatuses allow an integration of a circuit board with ultra-high density signal lines and supporting the component of the quantum processing units to be integrated with the thermalized magnetic shielding structure while maintaining their effectiveness and capabilities in thermal and electromagnetic management.

In some instances, the assembly can provide a rapid cooldown time for the quantum circuit on the quantum processor of the quantum processing unit. In certain instances, the cooldown time can be less than the typical cooldown time of a dilution refrigerator (e.g., 3-4 days); and thus reduce the thermal lag time. In some cases, the magnetic shielding structure can include a double layered design with openings interleaved to reject magnetic fields normal to the long axis of the magnetic shield structure. The quantum circuit can be mounted on a circuit board that penetrates the shields through a thin slot that is perpendicular to the axis of the face of the quantum circuit. In addition, the quantum circuit can be mounted near the bottom of the magnetic shielding structure, far from the slot, thereby reducing (e.g., minimizing) stray fields that are normal to the face of the quantum circuit. In some instances, a magnetic shielding factor on the order of 10⁵ relative to ambient fields may be achieved in some cases using the thermalized magnetic shielding structure in the present application.

In some implementations, the methods and apparatuses described here can provide technical advantages and improvements. For example, the methods and apparatuses presented here can provide a stable and uniform operating electromagnetic and thermal environment to quantum processing units over a large volume, and thus improve the performance of the quantum processing units, e.g., reduced error and decoherence, and enable large-scale quantum computation. For another example, the methods and apparatuses presented here can allow faster cooling time of the system, which can reduce system downtime, improve productivity, reduce maintenance cost, and provide other operational benefits. In some cases, a combination of these and potentially other advantages and improvements may be obtained.

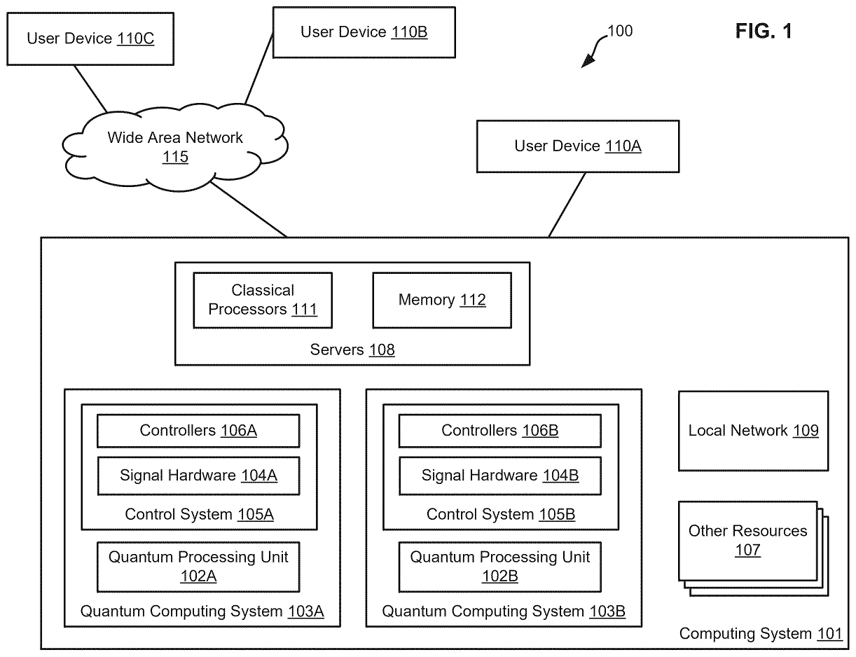

FIG. 1 is a block diagram of an example computing environment 100. The example computing environment 100 shown in FIG. 1 includes a computing system 101 and user devices 110A, 110B, 110C. A computing environment may include additional or different features, and the components of a computing environment may operate as described with respect to FIG. 1 or in another manner.

The example computing system 101 includes classical and quantum computing resources and exposes their functionality to the user devices 110A, 110B, 110C (referred to collectively as “user devices 110”). The computing system 101 shown in FIG. 1 includes one or more servers 108, quantum computing systems 103A, 103B, a local network 109 and other resources 107. The computing system 101 may also include one or more user devices (e.g., the user device 110A) as well as other features and components. A computing system may include additional or different features, and the components of a computing system may operate as described with respect to FIG. 1 or in another manner.

The example computing system 101 can provide services to the user devices 110, for example, as a cloud-based or remote-accessed computer system, as a distributed computing resource, as a supercomputer or another type of high-performance computing resource, or in another manner. The computing system 101 or the user devices 110 may also have access to one or more other quantum computing systems (e.g., quantum computing resources that are accessible through the wide area network 115, the local network 109 or otherwise).

The user devices 110 shown in FIG. 1 may include one or more classical processors, memory, user interfaces, communication interfaces, and other components. For instance, the user devices 110 may be implemented as laptop computers, desktop computers, smartphones, tablets or other types of computer devices. In the example shown in FIG. 1, to access computing resources of the computing system 101, the user devices 110 send information (e.g., programs, instructions, commands, requests, input data, etc.) to the servers 108; and in response, the user devices 110 receive information (e.g., application data, output data, prompts, alerts, notifications, results, etc.) from the servers 108. The user devices 110 may access services of the computing system 101 in another manner, and the computing system 101 may expose computing resources in another manner.

In the example shown in FIG. 1, the local user device 110A operates in a local environment with the servers 108 and other elements of the computing system 101. For instance, the user device 110A may be co-located with (e.g., located within 0.5 to 1 km of) the servers 108 and possibly other elements of the computing system 101. As shown in FIG. 1, the user device 110A communicates with the servers 108 through a local data connection.

The local data connection in FIG. 1 is provided by the local network 109. For example, some or all of the servers 108, the user device 110A, the quantum computing systems 103A, 103B and the other resources 107 may communicate with each other through the local network 109. In some implementations, the local network 109 operates as a communication channel that provides one or more low-latency communication pathways from the server 108 to the quantum computer systems 103A, 103B (or to one or more of the elements of the quantum computer systems 103A, 103B). The local network 109 can be implemented, for instance, as a wired or wireless Local Area Network, an Ethernet connection, or another type of wired or wireless connection. The local network 109 may include one or more wired or wireless routers, wireless access points (WAPs), wireless mesh nodes, switches, high-speed cables, or a combination of these and other types of local network hardware elements. In some cases, the local network 109 includes a software-defined network that provides communication among virtual resources, for example, among an array of virtual machines operating on the server 108 and possibly elsewhere.

In the example shown in FIG. 1, the remote user devices 110B, 110C operate remote from the servers 108 and other elements of the computing system 101. For instance, the user devices 110B, 110C may be located at a remote distance (e.g., more than 1 km, 10 km, 100 km, 1,000 km, 10,000 km, or farther) from the servers 108 and possibly other elements of the computing system 101. As shown in FIG. 1, each of the user devices 110B, 110C communicates with the servers 108 through a remote data connection.

The remote data connection in FIG. 1 is provided by a wide area network 115, which may include, for example, the Internet or another type of wide area communication network. In some cases, remote user devices use another type of remote data connection (e.g., satellite-based connections, a cellular network, a virtual private network, etc.) to access the servers 108. The wide area network 115 may include one or more internet servers, firewalls, service hubs, base stations, or a combination of these and other types of remote networking elements. Generally, the computing environment 100 can be accessible to any number of remote user devices.

The example servers 108 shown in FIG. 1 can manage interaction with the user devices 110 and utilization of the quantum and classical computing resources in the computing system 101. For example, based on information from the user devices 110, the servers 108 may delegate computational tasks to the quantum computing systems 103A, 103B and the other resources 107; the servers 108 can then send information to the user devices 110 based on output data from the computational tasks performed by the quantum computing systems 103A, 103B and the other resources 107.

As shown in FIG. 1, the servers 108 are classical computing resources that include classical processors 111 and memory 112. The servers 108 may also include one or more communication interfaces that allow the servers to communicate via the local network 109, the wide area network 115 and possibly other channels. In some implementations, the servers 108 may include a host server, an application server, a virtual server or a combination of these and other types of servers. The servers 108 may include additional or different features, and may operate as described with respect to FIG. 1 or in another manner.

The classical processors 111 can include various kinds of apparatus, devices, and machines for processing data, including, by way of example, a microprocessor, a central processing unit (CPU), a graphics processing unit (GPU), an FPGA (field programmable gate array), an ASIC (application specific integrated circuit), or combinations of these. The memory 112 can include, for example, a random access memory (RAM), a storage device (e.g., a writable read-only memory (ROM) or others), a hard disk, or another type of storage medium. The memory 112 can include various forms of volatile or non-volatile memory, media and memory devices, etc.

Each of the example quantum computing systems 103A, 103B operates as a quantum computing resource in the computing system 101. The other resources 107 may include additional quantum computing resources (e.g., quantum computing systems, quantum virtual machines (QVMs) or quantum simulators) as well as classical (non-quantum) computing resources such as, for example, digital microprocessors, specialized co-processor units (e.g., graphics processing units (GPUs), cryptographic co-processors, etc.), special purpose logic circuitry (e.g., field programmable gate arrays (FPGAs), application-specific integrated circuits (ASICs), etc.), systems-on-chips (SoCs), etc., or combinations of these and other types of computing modules.

In some implementations, the servers 108 generate programs, identify appropriate computing resources (e.g., a QPU or QVM) in the computing system 101 to execute the programs, and send the programs to the identified resources for execution. For example, the servers 108 may send programs to the quantum computing system 103A, the quantum computing system 103B or any of the other resources 107. The programs may include classical programs, quantum programs, hybrid classical/quantum programs, and may include any type of function, code, data, instruction set, etc.

In some instances, programs can be formatted as source code that can be rendered in human-readable form (e.g., as text) and can be compiled, for example, by a compiler running on the servers 108, on the quantum computing systems 103, or elsewhere. In some instances, programs can be formatted as compiled code, such as, for example, binary code (e.g., machine-level instructions) that can be executed directly by a computing resource. Each program may include instructions corresponding to computational tasks that, when performed by an appropriate computing resource, generate output data based on input data. For example, a program can include instructions formatted for a quantum computer system, a quantum virtual machine, a digital microprocessor, co-processor or other classical data processing apparatus, or another type of computing resource.

In some cases, a program may be expressed in a hardware-independent format. For example, quantum machine instructions may be provided in a quantum instruction language such as Quil, described in the publication “A Practical Quantum Instruction Set Architecture,” arXiv: 1608.03355v2, dated Feb. 17, 2017, or another quantum instruction language. For instance, the quantum machine instructions may be written in a format that can be executed by a broad range of quantum processing units or quantum virtual machines. In some cases, a program may be expressed in high-level terms of quantum logic gates or quantum algorithms, in lower-level terms of fundamental qubit rotations and controlled rotations, or in another form. In some cases, a program may be expressed in terms of control signals (e.g., pulse sequences, delays, etc.) and parameters for the control signals (e.g., frequencies, phases, durations, channels, etc.). In some cases, a program may be expressed in another form or format.

In some implementations, the servers 108 include one or more compilers that convert programs between formats. For example, the servers 108 may include a compiler that converts hardware-independent instructions to binary programs for execution by the quantum computing systems 103A, 103B. In some cases, a compiler can compile a program to a format that targets a specific quantum resource in the computer system 101. For example, a compiler may generate a different binary program (e.g., from the same source code) depending on whether the program is to be executed by the quantum computing system 103A or the quantum computing system 103B.

In some cases, a compiler generates a partial binary program that can be updated, for example, based on specific parameters. For instance, if a quantum program is to be executed iteratively on a quantum computing system with varying parameters on each iteration, the compiler may generate the binary program in a format that can be updated with specific parameter values at runtime (e.g., based on feedback from a prior iteration, or otherwise). In some cases, a compiler generates a full binary program that does not need to be updated or otherwise modified for execution.

In some implementations, the servers 108 generate a schedule for executing programs, allocate computing resources in the computing system 101 according to the schedule, and delegate the programs to the allocated computing resources. The servers 108 can receive, from each computing resource, output data from the execution of each program. Based on the output data, the servers 108 may generate additional programs that are then added to the schedule, output data that is provided back to a user device 110, or perform another type of action.

In some implementations, all or part of the computing environment operates as a cloud-based quantum computing (QC) environment, and the servers 108 operate as a host system for the cloud-based QC environment. The cloud-based QC environment may include software elements that operate on both the user devices 110 and the computer system 101 and interact with each other over the wide area network 115. For example, the cloud-based QC environment may provide a remote user interface, for example, through a browser or another type of application on the user devices 110. The remote user interface may include, for example, a graphical user interface or another type of user interface that obtains input provided by a user of the cloud-based QC environment. In some cases the remote user interface includes, or has access to, one or more application programming interfaces (APIs), command line interfaces, graphical user interfaces, or other elements that expose the services of the computer system 101 to the user devices 110.

In some cases, the cloud-based QC environment may be deployed in a “serverless” computing architecture. For instance, the cloud-based QC environment may provide on-demand access to a shared pool of configurable computing resources (e.g., networks, servers, storage, applications, services, quantum computing resources, classical computing resources, etc.) that can be provisioned for requests from user devices 110. Moreover, the cloud-based computing systems 104 may include or utilize other types of computing resources, such as, for example, edge computing, fog computing, etc.

In an example implementation of a cloud-based QC environment, the servers 108 may operate as a cloud provider that dynamically manages the allocation and provisioning of physical computing resources (e.g., GPUs, CPUs, QPUs, etc.). Accordingly, the servers 108 may provide services by defining virtualized resources for each user account. For instance, the virtualized resources may be formatted as virtual machine images, virtual machines, containers, or virtualized resources that can be provisioned for a user account and configured by a user. In some cases, the cloud-based QC environment is implemented using a resource such as, for example, OPENSTACK®. OPENSTACK® is an example of a software platform for cloud-based computing, which can be used to provide virtual servers and other virtual computing resources for users.

In some cases, the server 108 stores quantum machine images (QMI) for each user account. A quantum machine image may operate as a virtual computing resource for users of the cloud-based QC environment. For example, a QMI can provide a virtualized development and execution environment to develop and run programs (e.g., quantum programs or hybrid classical/quantum programs). When a QMI operates on the server 108, the QMI may engage either of the quantum processing units 102A, 102B, and interact with a remote user device (110B or 110C) to provide a user programming environment. The QMI may operate in close physical proximity to and have a low-latency communication link with the quantum computing systems 103A, 103B. In some implementations, remote user devices connect with QMIs operating on the servers 108 through secure shell (SSH) or other protocols over the wide area network 115.

In some implementations, all or part of the computing system 101 operates as a hybrid computing environment. For example, quantum programs can be formatted as hybrid classical/quantum programs that include instructions for execution by one or more quantum computing resources and instructions for execution by one or more classical resources. The servers 108 can allocate quantum and classical computing resources in the hybrid computing environment, and delegate programs to the allocated computing resources for execution. The quantum computing resources in the hybrid environment may include, for example, one or more quantum processing units (QPUs), one or more quantum virtual machines (QVMs), one or more quantum simulators, or possibly other types of quantum resources. The classical computing resources in the hybrid environment may include, for example, one or more digital microprocessors, one or more specialized co-processor units (e.g., graphics processing units (GPUs), cryptographic co-processors, etc.), special purpose logic circuitry (e.g., field programmable gate arrays (FPGAs), application-specific integrated circuits (ASICs), etc.), systems-on-chips (SoCs), or other types of computing modules.

In some cases, the servers 108 can select the type of computing resource (e.g., quantum or classical) to execute an individual program, or part of a program, in the computing system 101. For example, the servers 108 may select a particular quantum processing unit (QPU) or other computing resource based on availability of the resource, speed of the resource, information or state capacity of the resource, a performance metric (e.g., process fidelity) of the resource, or based on a combination of these and other factors. In some cases, the servers 108 can perform load balancing, resource testing and calibration, and other types of operations to improve or optimize computing performance.

Each of the example quantum computing systems 103A, 103B shown in FIG. 1 can perform quantum computational tasks by executing quantum machine instructions (e.g., a binary program compiled for the quantum computing system). In some implementations, a quantum computing system can perform quantum computation by storing and manipulating information within quantum states of a composite quantum system. For example, qubits (i.e., quantum bits) can be stored in and represented by an effective two-level sub-manifold of a quantum coherent physical system. In some instances, quantum logic can be executed in a manner that allows large-scale entanglement within the quantum system. Control signals can manipulate the quantum states of individual qubits and the joint states of multiple qubits. In some instances, information can be read out from the composite quantum system by measuring the quantum states of the qubits. In some implementations, the quantum states of the qubits are read out by measuring the transmitted or reflected signal from auxiliary quantum devices that are coupled to individual qubits.

In some implementations, a quantum computing system can operate using gate-based models for quantum computing. For example, the qubits can be initialized in an initial state, and a quantum logic circuit comprised of a series of quantum logic gates can be applied to transform the qubits and extract measurements representing the output of the quantum computation. Individual qubits may be controlled by single-qubit quantum logic gates, and pairs of qubits may be controlled by two-qubit quantum logic gates (e.g., entangling gates that are capable of generating entanglement between the pair of qubits). In some implementations, a quantum computing system can operate using adiabatic or annealing models for quantum computing. For instance, the qubits can be initialized in an initial state, and the controlling Hamiltonian can be transformed adiabatically by adjusting control parameters to another state that can be measured to obtain an output of the quantum computation.

In some models, fault-tolerance can be achieved by applying a set of high-fidelity control and measurement operations to the qubits. For example, quantum error correcting schemes can be deployed to achieve fault-tolerant quantum computation. Other computational regimes may be used; for example, quantum computing systems may operate in non-fault-tolerant regimes. In some implementations, a quantum computing system is constructed and operated according to a scalable quantum computing architecture. For example, in some cases, the architecture can be scaled to a large number of qubits to achieve large-scale general purpose coherent quantum computing. Other architectures may be used; for example, quantum computing systems may operate in small-scale or non-scalable architectures.

The example quantum computing system 103A shown in FIG. 1 includes a quantum processing unit 102A and a control system 105A, which controls the operation of the quantum processing unit 102A. Similarly, the example quantum computing system 103B includes a quantum processing unit 102B and a control system 105B, which controls the operation of a quantum processing unit 102B. A quantum computing system may include additional or different features, and the components of a quantum computing system may operate as described with respect to FIG. 1 or in another manner.

In some instances, all or part of the quantum processing unit 102A functions as a quantum processor, a quantum memory, or another type of subsystem. In some examples, the quantum processing unit 102A includes a quantum circuit system. The quantum circuit system may include qubit devices, readout devices and possibly other devices that are used to store and process quantum information. In some cases, the quantum processing unit 102A includes a superconducting circuit, and the qubit devices are implemented as circuit devices that include Josephson junctions, for example, in superconducting quantum interference device (SQUID) loops or other arrangements, and are controlled by radio-frequency signals, microwave signals, and bias signals delivered to the quantum processing unit 102A. In some cases, the quantum processing unit 102A includes an ion trap system, and the qubit devices are implemented as trapped ions controlled by optical signals delivered to the quantum processing unit 102A. In some cases, the quantum processing unit 102A includes a spin system, and the qubit devices are implemented as nuclear or electron spins controlled by microwave or radio-frequency signals delivered to the quantum processing unit 102A. The quantum processing unit 102A may be implemented based on another physical modality of quantum computing.

The quantum processing unit 102A may include, or may be deployed within, a controlled environment. The controlled environment can be provided, for example, by shielding equipment, cryogenic equipment, and other types of environmental control systems. In some examples, the components in the quantum processing unit 102A operate in a cryogenic temperature regime and are subject to very low electromagnetic and thermal noise. For example, magnetic shielding can be used to shield the system components from stray magnetic fields, optical shielding can be used to shield the system components from optical noise, thermal shielding and cryogenic equipment can be used to maintain the system components at controlled temperature, etc.

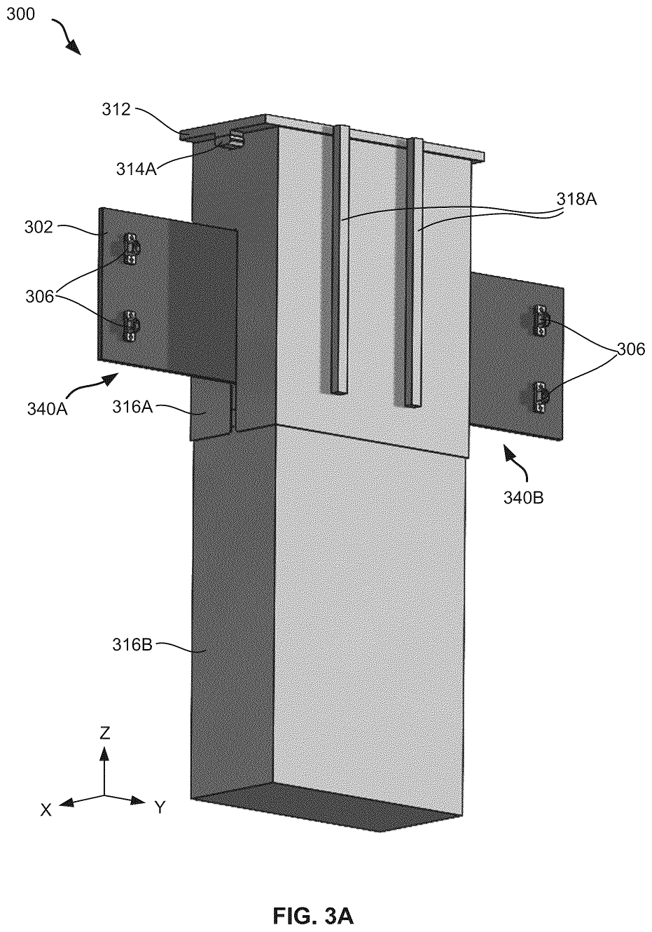

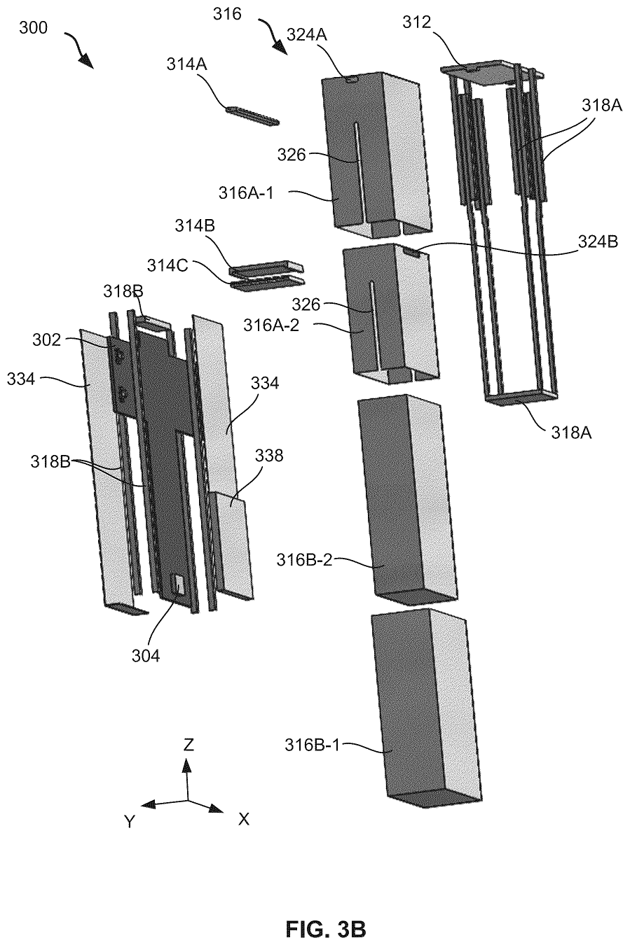

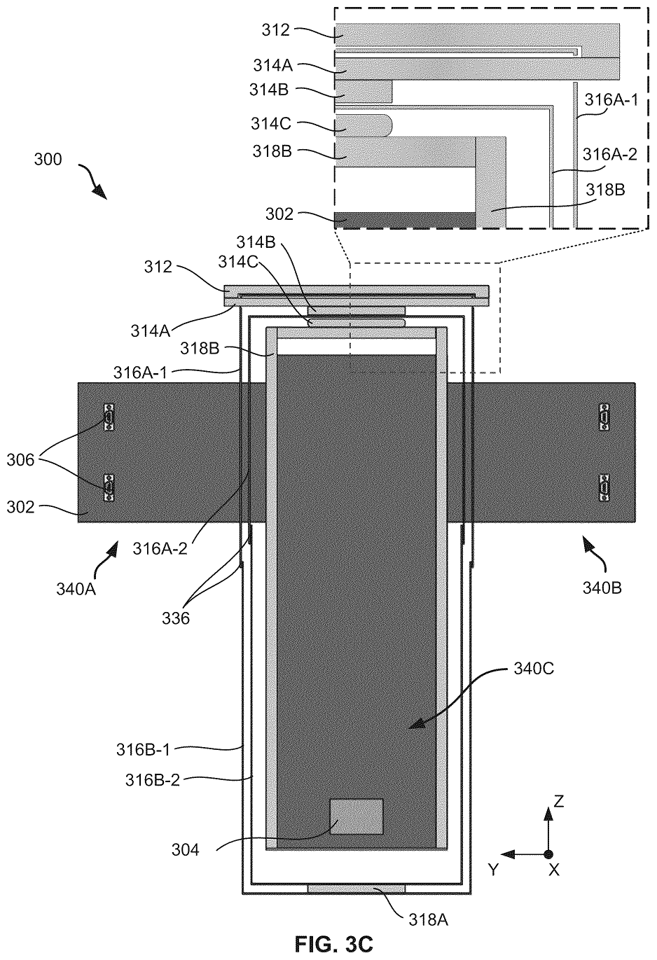

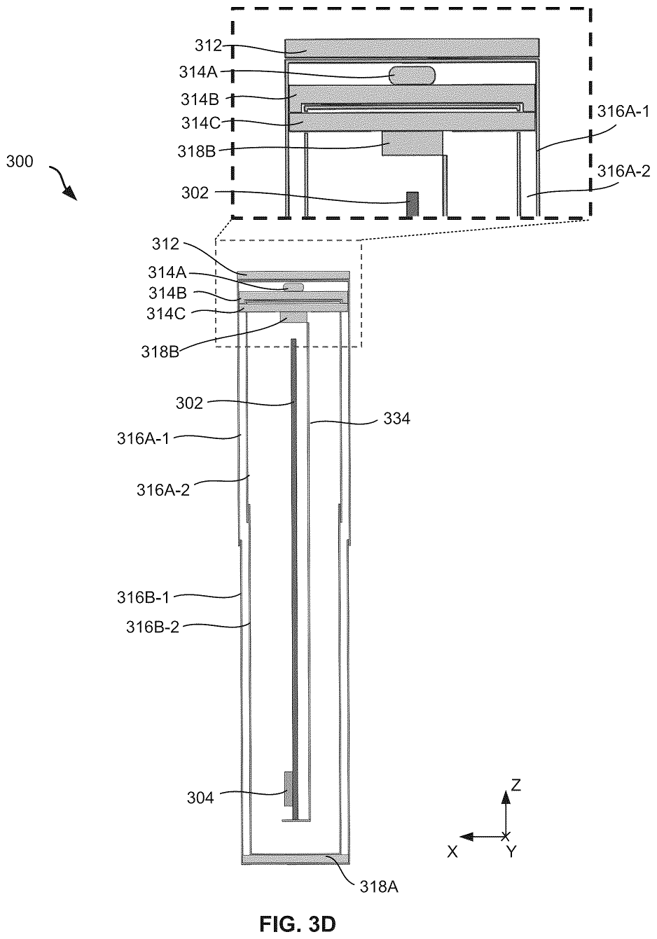

In some examples, the quantum processing unit 102A includes components (e.g., a quantum processor with a superconducting quantum circuit that are supported on a circuit board. At least one of the components of the quantum processing unit 102A can be enclosed in a magnetic shielding structure of an assembly. The circuit board may provide communication between the signal hardware 104A and the at least one of the components of the quantum processing unit 102A in the assembly; and the magnetic shielding structure of the assembly may provide multiple layers of magnetic shielding for the at least one of the components of the quantum processing unit 102A. The circuit board and the magnetic shielding structure are separately thermalized through distinct, independent thermalization pathways of the assembly to a common thermalization stage (e.g., a lowest-temperature thermalization stage). In some instances, the circuit board and the magnetic shielding structure may be implemented as the assembly 300 shown in FIGS. 3A-3D or in another manner. The thermalized magnetic shielding structure may reduce magnetic fields from reaching the components of the quantum processing unit 102A; and may reduce infrared radiation emitted from the magnetic shielding structure from reaching the at least one of the components of the quantum processing unit 102A allowing an improved cooling rate of the system.

In some implementations, the example quantum processing unit 102A can process quantum information by applying control signals to the qubits in the quantum processing unit 102A. The control signals can be configured to encode information in the qubits, to process the information by performing quantum logic gates or other types of operations, or to extract information from the qubits. In some examples, the operations can be expressed as single-qubit quantum logic gates, two-qubit quantum logic gates, or other types of quantum logic gates that operate on one or more qubits. A quantum logic circuit, which includes a sequence of quantum logic operations, can be applied to the qubits to perform a quantum algorithm. The quantum algorithm may correspond to a computational task, a hardware test, a quantum error correction procedure, a quantum state distillation procedure, or a combination of these and other types of operations.

In some implementations, the example quantum processing unit 102 is a modular quantum processing unit that includes multiple quantum processor modules. For example, the quantum processing unit 102 may include a two-dimensional or three-dimensional array of quantum processor modules, and each quantum processor module may include an array of quantum circuit devices. In some cases, the quantum processor modules are supported on a common substrate, and they are interconnected through circuitry (e.g., superconducting circuitry) on the common substrate.

In some instances, each of the quantum processor modules can include a superconducting quantum circuit that includes one or more quantum circuit devices and superconductive lines that connect the one or more quantum circuit devices. For instance, each quantum processor module may include qubit devices, readout resonator devices, tunable-frequency coupler devices, capacitive coupler devices, or other quantum circuit devices. Each quantum processor module may include flux bias control lines, microwave drive lines, readout signal lines, or other types of control lines for providing control signals to respective quantum circuit devices. In some implementations, quantum processor modules can be coupled to each other by inter-chip coupler devices in one or more cap structures.

The example control system 105A includes controllers 106A and signal hardware 104A. Similarly, control system 105B includes controllers 106B and signal hardware 104B. All or part of the control systems 105A, 105B can operate in a room-temperature environment or another type of environment, which may be located near the respective quantum processing units 102A, 102B. In some cases, the control systems 105A, 105B include classical computers, signaling equipment (microwave, radio, optical, bias, etc.), electronic systems, vacuum control systems, refrigerant control systems or other types of control systems that support operation of the quantum processing units 102A, 102B.

The control systems 105A, 105B may be implemented as distinct systems that operate independent of each other. In some cases, the control systems 105A, 105B may include one or more shared elements; for example, the control systems 105A, 105B may operate as a single control system that operates both quantum processing units 102A, 102B. Moreover, a single quantum computer system may include multiple quantum processing units, which may operate in the same controlled (e.g., cryogenic) environment or in separate environments.

The example signal hardware 104A includes components that communicate with the quantum processing unit 102A. The signal hardware 104A may include, for example, waveform generators, amplifiers, digitizers, high-frequency sources, DC sources, AC sources, etc. The signal hardware may include additional or different features and components. In the example shown, components of the signal hardware 104A are adapted to interact with the quantum processing unit 102A. For example, the signal hardware 104A can be configured to operate in a particular frequency range, configured to generate and process signals in a particular format, or the hardware may be adapted in another manner.

In some instances, one or more components of the signal hardware 104A generate control signals, for example, based on control information from the controllers 106A. The control signals can be delivered to the quantum processing unit 102A during operation of the quantum computing system 103A. For instance, the signal hardware 104A may generate signals to implement quantum logic operations, readout operations or other types of operations. As an example, the signal hardware 104A may include arbitrary waveform generators (AWGs) that generate electromagnetic waveforms (e.g., microwave or radiofrequency) or laser systems that generate optical waveforms. The waveforms or other types of signals generated by the signal hardware 104A can be delivered to devices in the quantum processing unit 102A to operate qubit devices, readout devices, bias devices, coupler devices or other types of components in the quantum processing unit 102A.

In some instances, the signal hardware 104A receives and processes signals from the quantum processing unit 102A. The received signals can be generated by the execution of a quantum program on the quantum computing system 103A. For instance, the signal hardware 104A may receive signals from the devices in the quantum processing unit 102A in response to readout or other operations performed by the quantum processing unit 102A. Signals received from the quantum processing unit 102A can be mixed, digitized, filtered, or otherwise processed by the signal hardware 104A to extract information, and the information extracted can be provided to the controllers 106A or handled in another manner. In some examples, the signal hardware 104A may include a digitizer that digitizes electromagnetic waveforms (e.g., microwave or radiofrequency) or optical signals, and a digitized waveform can be delivered to the controllers 106A or to other signal hardware components. In some instances, the controllers 106A process the information from the signal hardware 104A and provide feedback to the signal hardware 104A; based on the feedback, the signal hardware 104A can in turn generate new control signals that are delivered to the quantum processing unit 102A.

In some implementations, the signal hardware 104A includes signal delivery hardware that interfaces with the quantum processing unit 102A. For example, the signal hardware 104A may include filters, attenuators, directional couplers, multiplexers, diplexers, bias components, signal channels, isolators, amplifiers, power dividers and other types of components. In some instances, the signal delivery hardware performs preprocessing, signal conditioning, or other operations to the control signals to be delivered to the quantum processing unit 102A. In some instances, signal delivery hardware performs preprocessing, signal conditioning or other operations on readout signals received from the quantum processing unit 102A.

The example controllers 106A communicate with the signal hardware 104A to control the operation of the quantum computing system 103A. The controllers 106A may include classical computing hardware that directly interfaces with components of the signal hardware 104A. The example controllers 106A may include classical processors, memory, clocks, digital circuitry, analog circuitry, and other types of systems or subsystems. The classical processors may include one or more single- or multi-core microprocessors, digital electronic controllers, special purpose logic circuitry, e.g., an FPGA (field programmable gate array) or an ASIC (application specific integrated circuit), or other types of data processing apparatus. The memory may include any type of volatile or non-volatile memory or another type of computer storage medium. The controllers 106A may also include one or more communication interfaces that allow the controllers 106A to communicate via the local network 109 and possibly other channels. The controllers 106A may include additional or different features and components.

In some implementations, the controllers 106A include memory or other components that store quantum state information, for example, based on qubit readout operations performed by the quantum computing system 103A. For instance, the states of one or more qubits in the quantum processing unit 102A can be measured by qubit readout operations, and the measured state information can be stored in a cache or other type of memory system in or more of the controllers 106A. In some cases, the measured state information is subsequently used in the execution of a quantum program, a quantum error correction procedure, a quantum processing unit (QPU) calibration or testing procedure, or another type of quantum process.

In some implementations, the controllers 106A include memory or other components that store a quantum program containing quantum machine instructions for execution by the quantum computing system 103A. In some instances, the controllers 106A can interpret the quantum machine instructions and perform hardware-specific control operations according to the quantum machine instructions. For example, the controllers 106A may cause the signal hardware 104A to generate control signals that are delivered to the quantum processing unit 102A to execute the quantum machine instructions.

In some instances, the controllers 106A extract qubit state information from qubit readout signals, for example, to identify the quantum states of qubits in the quantum processing unit 102A or for other purposes. For example, the controllers may receive the qubit readout signals (e.g., in the form of analog waveforms) from the signal hardware 104A, digitize the qubit readout signals, and extract qubit state information from the digitized signals. In some cases, the controllers 106A compute measurement statistics based on qubit state information from multiple shots of a quantum program. For example, each shot may produce a bitstring representing qubit state measurements for a single execution of the quantum program, and a collection of bitsrings from multiple shots may be analyzed to compute quantum state probabilities.

In some implementations, the controllers 106A include one or more clocks that control the timing of operations. For example, operations performed by the controllers 106A may be scheduled for execution over a series of clock cycles, and clock signals from one or more clocks can be used to control the relative timing of each operation or groups of operations. In some implementations, the controllers 106A may include classical computer resources that perform some or all of the operations of the servers 108 described above. For example, the controllers 106A may operate a compiler to generate binary programs (e.g., full or partial binary programs) from source code; the controllers 106A may include an optimizer that performs classical computational tasks of a hybrid classical/quantum program; the controllers 106A may update binary programs (e.g., at runtime) to include new parameters based on an output of the optimizer, etc.

The other quantum computer system 103B and its components (e.g., the quantum processing unit 102B, the signal hardware 104B and controllers 106B) can be implemented as described above with respect to the quantum computer system 103A; in some cases, the quantum computer system 103B and its components may be implemented or may operate in another manner.

In some implementations, the quantum computer systems 103A, 103B are disparate systems that provide distinct modalities of quantum computation. For example, the computer system 101 may include both an adiabatic quantum computer system and a gate-based quantum computer system. As another example, the computer system 101 may include a superconducting circuit-based quantum computer system and an ion trap-based quantum computer system. In such cases, the computer system 101 may utilize each quantum computing system according to the type of quantum program that is being executed, according to availability or capacity, or based on other considerations.

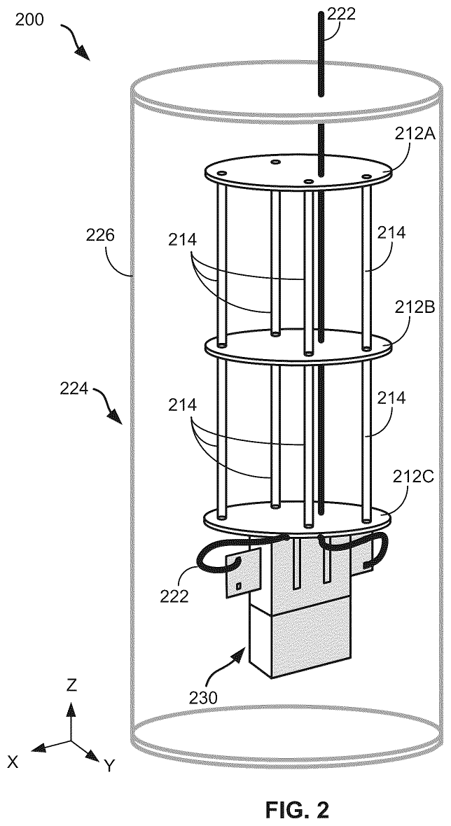

FIG. 2 is a diagram showing aspects of an example cryostat 200 in a quantum computing system. As shown in FIG. 2, the example cryostat 200 includes a dilution refrigerator system 224 with multiple thermalization stages 212A, 212B, 212C. In some implementations, the example dilution refrigerator system 224 may be used to expose devices and samples to environments of very low temperature (e.g., T<120 K). In some implementations, vacuum cryostats are used for thermal isolation, typically having a pressure in the range of 0.1 to 10⁻⁷ Pascal, thereby allowing the example dilution refrigerator system 224 to operate at stable temperatures without appreciable thermal losses.

In some implementations, the one or more thermalization stages 212 may correspond to radiation shields, thermalization plates, or both. In some instances, a thermalization stage 212 in the dilution refrigerator system 224 may be formed of a material having a high thermal conductivity at cryogenic temperatures, such as below 120 K. For example, a thermalization stage 212 may be formed of a material having a thermal conductivity of at least 1 W/(m·K) as measured at 4 K. In some examples, a high thermal conductivity allows the thermalization stage 212 to mitigate the development of temperature gradients, thereby maintaining a substantially uniform temperature across their respective masses. In some implementations, such material in a thermalization stage 212 may include oxygen-free high conductivity copper and its alloys, including a C101 copper alloy or a beryllium-copper alloy (e.g., Cu with 0.5-3% Be) or another type of alloy.

In some instances, the dilution refrigerator system 224 may include any number of thermalization stages 212 to support subsystems, devices, and samples for cryogenic refrigeration. As a result, the dilution refrigerator system 224 may position the thermalization stages 212 to define a spatial sequence of thermalization stages, such as in a linear sequence or an angular sequence. FIG. 2 depicts three thermalization stages 212 in an equally spaced linear sequence. In some implementations, the dilution refrigerator system 224 may include any number and spacing of thermalization stages 212 as needed. In the example shown in FIG. 2, the dilution refrigerator system 224 includes one or more structural supports 214 to position the thermalization stages 212 into the spatial sequence of thermalization stages. In some examples, the structural supports 214 may be formed of a material having a low thermal conductivity at cryogenic temperatures, e.g., less than 0.5 W/(m·K) at or below 50 K, such as a stainless-steel alloy or a glass-epoxy laminate of G10 grade. In this case, the structural supports 214 thus additionally impede a flow of heat between the thermalization stages 212. As such, the dilution refrigerator system 224 may include one or more thermalization stages 212 dedicated to a specific temperature during operation. For example, the dilution refrigerator system 224 may be configured such that each thermalization stage 212 operates at a progressively decreasing temperature as the depth of the dilution refrigerator system 224 increases along the Z axis.

In some implementations, the dilution refrigerator system 224 may also include one or more refrigeration systems (not shown) thermally coupled to each of the thermalization stages 212. For example, the dilution refrigerator system 224 may include a pulse-tube refrigeration system coupled to a second lowest-temperature thermalization stage 212B and a ³He/⁴He dilution refrigerator system thermally coupled to a lowest-temperature thermalization stage 212C. The dilution refrigerator system 224 establishes specific operating temperatures for the thermalization stages 212 to which they are respectively thermally coupled. In some implementations, the dilution refrigerator system 224 may define a distribution of operating temperatures along the spatial sequence of thermalization stages 212. In some implementations, a pulse-tube refrigeration unit may be configured to optimally extract heat at temperatures to about 4 K and a ³He/⁴He dilution refrigerator unit may be configured to optimally extract heat at temperatures below 1 K.

In some implementations, the example cryostat 200 includes an assembly 230 supported on a thermalization stage and enclosed in the dilution refrigerator system 224. As shown in FIG. 2, the assembly 230 is configured on the lowest-temperature thermalization stage 212C of the dilution refrigerator system 224. In some implementations, the example assembly 230 includes a magnetic shielding structure. The example assembly 230 holds a circuit board. In some implementations, the magnetic shielding structure of the assembly 230 can be configured to create a barrier that blocks or redirects magnetic fields from at least a portion of the circuit board where a quantum processing unit is supported. In particular, the magnetic shielding structure of the assembly 230 can effectively shield the quantum processing unit from magnetic fields that are perpendicular to the surface of the quantum processing unit. In some instances, the magnetic shielding structure includes materials that have high levels of magnetic permeability, e.g., nickel-iron (Ni—Fe) alloy, nickel-molybdenum (Ni—Mo), ferrite, superconductive materials, amorphous metal, conductive polymer, or other types of materials. As shown in FIG. 2, the assembly 230 extends along the Z-axis perpendicular to the surface of the lowest-temperature thermalization stage 212C which is in the X-Y plane. In some instances, the assembly 230 may be oriented relative to the lowest-temperature thermalization stage 212C or other thermalization stages of dilution refrigerator system 224 in a different manner.

In some implementations, the surfaces of the magnetic shielding structure of the assembly 230 are treated to improve their thermal conductivity properties. For example, the surfaces of the magnetic shielding structure may include a thermalization coating on both inner and outer surfaces to improve the thermal conductivity of the magnetic shielding structure. In some instances, the thermalization coating to improve the thermal conductivity of the magnetic shielding structure includes a thermally conductive material such as metal, metal superlattice, metal alloy, metal oxide, ceramic, or another type of material. In some instances, the surface treatment approach used to improve the thermal conductivity of the magnetic shielding structure does not degrade their magnetic shielding effectiveness. In some instances, the thermal conductivity of the magnetic shielding structure of the assembly 230 may be improved in another manner.

In some instances, the circuit board and the surface-treated magnetic shielding cans of the assembly 230 are independently thermally anchored to and in thermal contact with the lowest-temperature thermalization stage 212C via separate thermalization pathways. In other words, heat generated in the circuit board can be dissipated to the thermalization stage; and the magnetic shielding structure can be separately thermalized to reduce heat radiation to the components (e.g., the quantum circuit of the quantum processor) of the quantum processing unit residing inside the magnetic shielding structure. In some implementations, the circuit board may be implemented as the circuit board 302; and the magnetic shielding structure can be implemented as the magnetic shielding cans 316A, 316B shown in FIGS. 3A-3D or in another manner. In some implementations, the assembly 230 can provide technical advantages. The assembly 230 can improve the performance of the quantum processing unit and reduce the cooling time of the system. In some instances, the cooldown rate of the magnetic shielding structure through the frame is on the order of several days, allowing for any radiation from them to be limited to this time period, which is on the order of the time that the entire system takes to cool down.

In some implementations, the assembly 230 can be implemented as the assembly 300 shown in FIGS. 3A-3D, which has a rectangular prism shape. In some instances, the assembly 230 may be implemented in another manner. For example, the assembly 230 may have a different three-dimensional geometric shape, e.g., rectangular prism with rounded corners, cylindrical, sphere, ovoid, ellipsoid, cone, irregular, or another three-dimensional geometric shape.

In some implementations, the quantum processing unit on the circuit board enclosed in the magnetic shielding structure of the assembly 230 may receive and transmit signals via transmission links 222. The transmission links 222 can transmit control signals to the quantum processing unit, and readout signals from the quantum processing unit out of the dilution refrigerator system 224. In some instances, the signals communicated on the transmission links 222 are microwave-frequency signals, radiofrequency signals, or other types of communication signals. As shown in FIG. 2, the transmission links 222 in the dilution refrigerator system 224 are configured separately from the structural supports 214 through the thermalization stages 212. In certain instances, the transmission links 222 may be arranged or routed in another manner to couple signal hardware in the control system (e.g., the signal hardware 104 in the control system 105 in FIG. 1).

In some instances, the circuit board and the magnetic shielding structure are independently mounted to the lowest-temperature thermalization stage 212C in a way that there is no line of sight through the penetrations. In some instances, the circuit board extends (along the X-Y plane) continuously through slots along a first direction on the magnetic shielding structure such that a first end portion of the circuit board resides outside the slots of the magnetic shielding structure; a second opposite end portion of the circuit board residing outside the slots of the magnetic shielding structure, and a central portion of the circuit board resides in the magnetic shielding structure. The central portion of the circuit board also extends inside the magnetic shielding structure in a second, distinct direction, which may be normal to the first direction (along the Z-axis). The quantum processing unit residing on the extended central portion of the circuit board is away from the slots where the circuit board protrudes the magnetic shielding structure. In some instances, this configuration may allow the minimization or reduction of the effect of magnetic fields leaking into the magnetic shielding structure through the slots on the quantum processing unit. In some implementations, the circuit board is a printed circuit board, or another type of circuit board. In some implementations, the circuit board may be configured in another manner. For example, the circuit board may have a different shape. For another example, the circuit board may be completely enclosed by the magnetic shielding structure; and in this case, the magnetic shielding structure may include fittings, connections, or other parts that allow communication links 222 to communicate with the circuit board inside the magnetic shielding structure.

In some instances, the circuit board includes impedance-matched lines for RF signals, low resistance lines for DC signals, or other types of signal lines allowing for high-density RF- and DC-signals passing through electrical connectors to the quantum processing unit. In some examples, the circuit board may be a multilayered circuit board with multiple metallization layers; may include an array of electrically and thermally conductive through hole vias; and may include additional or different features. In some instances, the circuit board includes superconducting materials to allow for lower electrical resistance operations at cryogenic environment without significantly increasing the thermal conductance.

In some implementations, the circuit board may include two or more quantum processing units; and each quantum processing unit includes qubit devices and other quantum circuit devices in a range of 40 to 100 devices, for example. This approach can be scaled such that the quantum processing units integrated on the circuit board can operate up to ˜10,000 or more qubit devices. The circuit board with a high density of signal lines (e.g., in a range of greater than or equal to 0.2 signals/mm² or another range) can be used for communicating electrical signals (e.g., control signals and readout signals) between the quantum circuit devices of the quantum processing units in the assembly 230 with a control system outside of the cryostat 200 through the communication links 222.

FIGS. 3A-3D include schematic diagrams showing a perspective view, an exploded view, a first cross-sectional view, and a second cross-sectional view of an example assembly 300. As shown in FIGS. 3A-3D, the example assembly 300 includes a magnetic shielding structure 316, thermalization frames 318, and interleaved circuit board brackets 314A, 314B, 314C. The magnetic shielding structure 316 defines an interior volume to contain at least one component of the quantum processing unit 304 residing on a circuit board 302. The magnetic shielding structure 316 includes two layers of magnetic shielding cans 316A-1, 316A-2, 316B-1, 316B-2. The example assembly 300 may include additional or different features, and the components of the example assembly 300 may be configured as described with respect to FIGS. 3A-3D or in another manner. For example, the magnetic shielding structure 316 may include more than two layers of magnetic shielding cans; and the magnetic shielding structure may have a different shape.

As shown in FIGS. 3A-3D, a first end portion 340A and a second end portion 340B of the circuit board 302 include electrical connectors 306 that are configured to interface with communication links (e.g., electrical cables). In some instances, the electrical connectors 306 may be configured to interface with flat circuit cables, flat printed circuit cables, or other type of flex cables. In some instances, the electrical connectors 306 may be flat circuit connectors or other types of electrical connectors.

In some implementations, the circuit board 302 includes electrical circuitry configured to communicate electrical signals between the electrical connectors 306 on the first and second end portions 340A, 340B of the circuit board 302 and the quantum processor 304 at a central portion 340C of the circuit board 302. In some implementations, the electrical circuitry includes signal lines extending from the first end portion 340A and the second end portion 340B, through the central portion 340C, into the quantum processing unit 304. In some instances, the signal lines may be planar transmission lines, for example coplanar waveguides, substrate integrated waveguides or other types of planar transmission lines. In some implementations, the electrical circuitry of the circuit board 302 includes circuit elements. The circuit elements may be mounted on or in the circuit board 302 connected to at least a subset of the signal lines of the circuit board 302. In some instances, the circuit elements may include one or more passive and/or active radio frequency (RF) circuit devices, e.g., filters, attenuators, amplifiers, and other types of circuit elements for signal conditioning and/or processing. In some instances, the circuit board 302 may be a multi-layered circuit board including a stack of metallization layers. Each of the metallization layers includes a respective portion of the electrical circuitry.

After assembly, the circuit board 302 protrudes continuously through the magnetic shielding structure 316 from the outside of a first outer magnetic shielding can 316A-1 to the inside of a first inner magnetic shielding cans 316A-2. As shown in FIGS. 3A-3D, the first and second end portions of the circuit board 340A, 340B reside outside the magnetic shielding structure 316, while the central portion 340C reside in the magnetic shielding structure 316. In some implementations, the methods and systems presented here allow the removal of any electrical cabling from inside the shielding cans; and allow for smaller shielding cans and thus better shielding effect.

As shown in FIGS. 3A-3D, the circuit board 302 and each of the magnetic shielding cans 316A-1, 316A-2, 316B-1, 316B-2 of the magnetic shielding structure 316 are thermalized to a top plate 312 via respective thermalization frames 318A, 318B and interleaved circuit board brackets 314A, 314B, 314C. In some implementations, the top plate is thermalized to a thermalization stage of a cryostat, e.g., the lowest-temperature thermalization stage 214C of the cryostat 200 in FIG. 2, or another thermalization stage. As shown in FIGS. 3A-3D, the circuit board 302 and the magnetic shielding cans 316A-1, 316A-2, 316B-1, 316B-2 are effectively thermalized to the common top plate 312 via two separate thermalization pathways to the common top plate 312.

In particular, both the inner and outer surfaces of the magnetic shielding cans 316A-1, 316A-2, 316B-1, 316B-2 are thermalized to the top plate 312 via a first set of thermalization frames 318A and interleaved circuit board brackets 314A, 314B. In other words, the first set of thermalization frames 318A and interleaved circuit board brackets 314A, 314B provides thermal contact between the top plate 312 and the magnetic shielding cans 316A-1, 316A-2, 316B-1, 316B-2. In some implementations, the first set of thermalization frames 318A contacts both inner and outer surfaces of all magnetic shielding cans 316A-1, 316A-2, 316B-1, 316B-2. In some instances, the interleaved circuit board brackets 314A, 314B, 314C and the top plate 312 are fastened to one another in a sequence, for example, using fasteners through alignment holes in the interleaved circuit board brackets 314A, 314B, 314C or in another manner, such that the interleaved circuit board brackets 314A, 314B, 314C are effectively thermalized to one another. In some instances, the interleaved circuit boards 314A, 314B are also interleaved with the magnetic shielding cans 316A-1, 316A-2 through respective holes 324A, 324B such that the magnetic shielding cans 316A-1, 316A-2 are mechanically mounted and suspended on the top plate 312. In some instances, the first set of frames 318A is configured to mechanically mount the magnetic shielding cans 316A-1, 316A,2, 316B-1, 316B-2 and thermalize them to the top plate 312.

Similarly, the surfaces of the circuit board 302 are thermalized to the top plate 312 via a second set of thermalization frames 318B and the interleaved circuit board brackets 314A, 314B, 314C such that heat generated on the circuit board 302 can be dissipated to the thermalization stage via the second set of thermalization frames 318B, the interleaved circuit board brackets 314A, 314B, 314C, and the top plate 312. In other words, the second set of thermalization frames 318B and the interleaved circuit board brackets 314A, 314B, 314C provide thermal contact between the top plate 312 and the circuit board 302.

In some implementations, the two pairs of magnetic shielding cans 316A-1/316B-1, 316A-2/316B-2 provide two layers of magnetic shielding to reject or absorb external magnetic field along the X-axis and Y-axis perpendicular to the Z-axis of the assembly 300. As shown in FIGS. 3C-3D, each of the magnetic shielding cans 316A-1, 316A-2, 316B-1, 316B-2 includes a respective lid in the X-Y plane configured as a barrier for shielding magnetic fields along the Z axis of the assembly 300.

As shown in FIGS. 3A-3D, the example assembly 300 includes radiation absorbing material 336 at the junction between a pair of two magnetic shielding cans 316A-1/316B-1, 316A-2/316B-2. The absorbing material 336 is configured to prevent or reduce external infrared, radiofrequency, or other types of radiation from leaking into the interior volume defined by the magnetic shielding structure 316 and onto the component of the quantum processing unit 304. The radiation absorbing material 336 includes materials that have low thermal conductivity. For example, the radiation absorbing material 336 may be ECCOSORB® AN absorber or other radiation absorbing material. As shown in FIGS. 3C-3D, the magnetic shielding cans in a pair, e.g., 316A-1/316B-1, 316A-2/316B-2 are nest together or are interleaved at the area around the absorbing material 336 to reject or absorb external magnetic field.

In some implementations, the interleaved circuit board brackets 314A, 314B, 314C, the first and second subsets of thermalization frames 318A, 318B, and the top plate 302 contain materials that have high thermal conductivity which allows heat dissipation from the circuit board 302 and the magnetic shielding cans 316A, 316B to the thermalization stage (e.g., the lowest-temperature thermalization stage 212C in FIG. 2). In some instances, the interleaved circuit board brackets 314A, 314B, 314C, the first and second subsets of thermalization frames 318A, 318B, and the top plate 302 may be made of the same material as the thermalization stage.

As shown in FIG. 3B, the example assembly 300 further includes an infrared shielding can 334 configured to protect quantum processing unit 304 residing at the central portion 340C of the circuit board 302 from infrared radiation from the first set of thermalization frames 318A, the interleaved circuit board brackets 314A, 314Ab, 314C, the top plate 314, and other components of the example assembly 300. In some implementations, the infrared shielding can 334 include a material that is designed to reduce or block the transmission of infrared radiation, including metal, carbon-based materials, ceramic, and other types of materials. In some instances, the infrared shielding can 334 includes a door 338 for easy access to the quantum processing unit 304 on the circuit board 302.

In some implementations, both the inner and outer surfaces of each of the magnetic shielding cans 316A-1/316B-1, 316A-2/316B-2 are treated to improve the thermal conductivity of the magnetic shielding cans 316A-1/316B-1, 316A-2/316B-2 while maintain their effectiveness in magnetic shielding. The surface treatment applied to the magnetic shielding cans 316A-1/316B-1, 316A-2/316B-2 includes plating a copper layer and a gold layer on the magnetic shielding structure 316. In some instances, the thickness of the copper layer can be tuned to improve thermal conductivity. The thickness of the copper layer is equal to or greater than 100 nanometers (nm), 200 nm, 500 nm, 1 micrometer (μm), or another value. In some instances, the gold layer is plated on top of the Cu layer to protect the surface of the Cu layer from oxidation. In some instances, the thickness of the gold layer is greater than or equal to 10 nm, 20 nm, 50 nm, 100 nm or in another range. In some instances, the surface treatment coating includes a multilayer structure with alternating layers of two or more metals. By controlling geometric properties (e.g., roughness, layer thicknesses, etc.), thermal conducting properties, phonon-blocking properties, and other material properties, thermal conducting properties can be tuned.

As shown in FIGS. 3A-3D, the magnetic shielding cans 316A-1, 316A-2 have slots 326 that allow the circuit board 302 to penetrate both layers of the magnetic shielding cans 316A-1, 316A-2. In particular, the slots are configured to extend through the magnetic shielding cans 316A-1, 316A-2 along a direction perpendicular to the extending direction of the assembly 230, e.g., Z-axis. In this case, the axis of magnetic fields that can penetrate the slot is parallel to the plane on which the quantum processing unit 304 resides, reducing the effects on the quantum processing unit 304 of magnetic fields that thread through the slots 326.

In some implementations, the circuit board 302 is mechanically in contact with and thermalized to the interleaved circuit board brackets 314A, 314B, 314C and the second set of thermalization frames 318B. Each of the slot 326 on the magnetic shielding cans 316A-1, 316A-2 has a geometric dimension that is large enough to separate the circuit board 302 from direct contact with the magnetic shielding cans 316A-1, 316A-2 preventing the formation of a thermal link. In some implementations, the systems and techniques presented here allow the circuit board 302 to cool down to a desired temperature in less than one day; and the cooling rate of the circuit board 302 is limited primarily by the cooling rate of the thermalization stage. In some instances, a sealant material can be included between the edges of the slots 326 of the magnetic shielding cans 316A-1, 316A-2 and the circuit board 302 to inhibit leaking of any infrared, radiofrequency, or other radiation into the interior volume defined by the magnetic shielding structure 316 to affect the operation of the quantum processor of the quantum processing unit 302 on the circuit board 304.

In some implementations, the components of the quantum processing unit 304 residing on the circuit board 302 and inside the magnetic shielding structure 316 of the assembly 300 includes a superconducting quantum circuit of a quantum processor. In certain instances, the superconducting quantum circuit of the quantum processing unit includes quantum circuit devices, such as qubit devices (e.g., transmon devices, fluxonium devices, or other types of superconducting qubit devices), coupler devices, readout resonators, or other types of quantum circuit devices that are used for quantum information processing in the quantum processing unit. In some examples, each of the qubit devices in a quantum processing unit can be encoded with a single bit of quantum information. The quantum circuit devices may include one or more Josephson junctions, capacitors, inductors, and other types of circuit elements.

In some implementations, the superconducting quantum circuit on the quantum processing unit 304 may further include a variety of circuit elements to control or readout the qubit devices of the quantum processing unit. For example, the superconducting quantum circuit may include flux bias lines which can provide magnetic flux locally to tunable-frequency qubit devices to tune their frequencies. The superconducting quantum circuit may include tunable coupler devices, microwave feedlines, and resonator devices to readout qubits. In some examples, the superconducting quantum circuit may include microwave feedlines which are coupled to one or several of the resonator devices quantum processing unit 304 to allow microwave excitation of the resonator devices used to readout qubits. In this case, the superconducting quantum circuit may include microwave drive lines which are capacitively coupled to qubit devices to drive qubits.

Typically, each of the qubit devices has two eigenstates that are used as computational basis states (e.g., |0 [symbol] and |1 [symbol] ), and each qubit device can transition between its computational basis states or exist in an arbitrary superposition of its computational basis states. In some examples, the two lowest energy levels (e.g., the ground state and first excited state) of each qubit device are defined as a qubit and used as computational basis states for quantum computation. In some examples, higher energy levels (e.g., a second excited state or a third excited state) can be used to define a qubit, a qutrit, a qudit, or a multi-level quantum computational device in some instances. Quantum states (e.g., qubits) defined by respective qubit devices can be manipulated by control signals, or read by readout signals, generated by a control system, e.g., the control system 105 in FIG. 1. The qubit devices can be controlled individually, for example, by delivering control signals from a control system to the respective qubit devices. In some cases, readout devices can detect the states of the qubit devices, for example, by interacting directly with the respective qubit devices.

The superconducting quantum circuit in the quantum processing unit 304 may be fabricated on a substrate. In certain instances, the substrate supporting the superconducting quantum circuit may be an elemental semiconductor, for example silicon (Si), germanium (Ge), selenium (Se), tellurium (Te), or another elemental semiconductor. In some instances, the substrate may also include a compound semiconductor such as aluminum oxide (sapphire), silicon carbide (SiC), gallium arsenic (GaAs), indium arsenide (InAs), indium phosphide (InP), silicon germanium (SiGe), silicon germanium carbide (SiGeC), gallium arsenic phosphide (GaAsP), gallium indium phosphide (GaInP), or another compound semiconductor. In some instances, the substrate may also include a multilayer structure with elemental or compound semiconductor layers. In certain instances, the substrate includes an epitaxial layer. In some examples, the substrate may have an epitaxial layer overlying a bulk semiconductor or may include a semiconductor-on-insulator (SOI) structure.

The superconducting quantum circuit may include superconductive materials and can be formed by patterning one or more superconductive (e.g., superconducting metal) layers or other materials. In some implementations, each of the one or more superconductive layers include a superconducting metal, such as aluminum (Al), niobium (Nb), rhenium (Re), tantalum (Ta), titanium (Ti), vanadium (V), tungsten (W), zirconium (Zr), or another superconducting metal. In some implementations, each of the one or more superconductive layers may include a superconducting metal alloy, such as molybdenum-rhenium (Mo/Re), niobium-tin (Nb/Sn), or another superconducting metal alloy. In some implementations, each of the superconductive layers may include a superconducting compound material, including superconducting metal nitrides and superconducting metal oxides, such as titanium-nitride (TiN), niobium-nitride (NbN), zirconium-nitride (ZrN), hafnium-nitride (HfN), vanadium-nitride (VN), tantalum-nitride (TaN), molybdenum-nitride (MoN), yttrium barium copper oxide (Y—Ba—Cu—O), or another superconducting compound material. In some instances, the superconducting quantum circuit may include multilayer superconductor-insulator heterostructures.

In some implementations, the quantum processing unit 304 is fabricated on the top surface of a substrate and patterned using a microfabrication process or in another manner. For example, quantum circuit devices in a superconducting quantum circuit may be formed by performing at least some of the following fabrication steps: using chemical vapor deposition (CVD), physical vapor deposition (PVD), atomic layer deposition (ALD), spin-on coating, and/or other suitable techniques to deposit respective superconducting layers on the substrate; and performing one or more patterning processes (e.g., a lithography process, a dry/wet etching process, a soft/hard baking process, a cleaning process, etc.) to form openings in the respective superconducting layers.

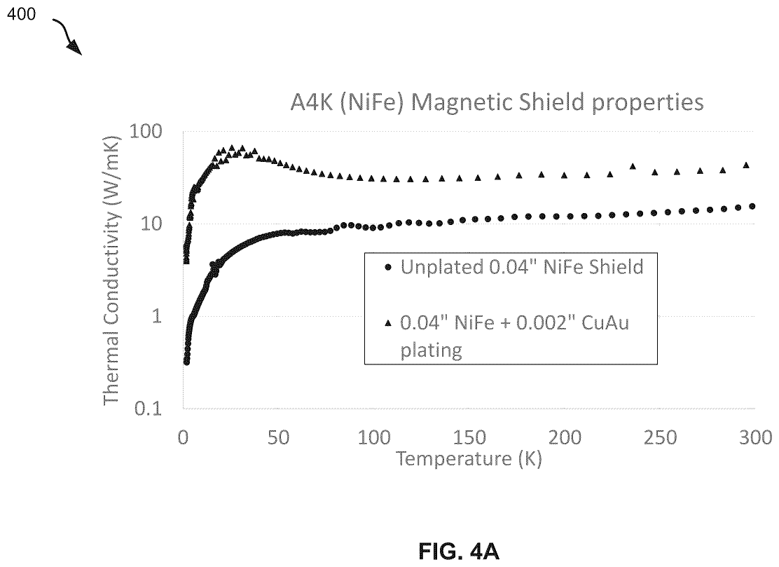

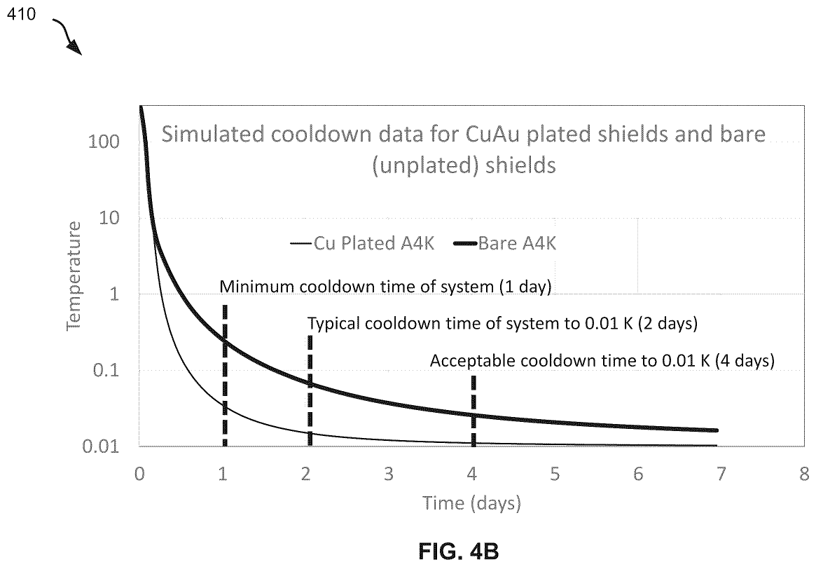

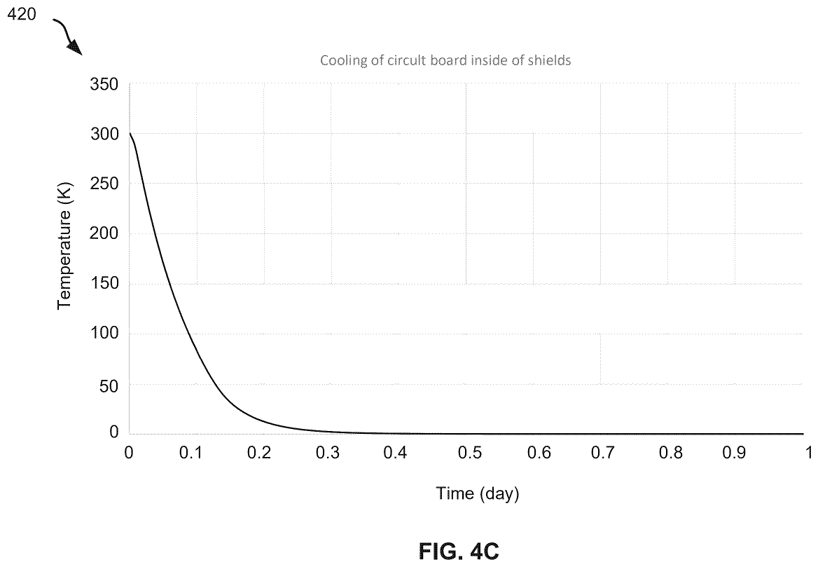

FIG. 4A is a plot 400 showing the thermal conductivity in watts per meter per kelvin (W/m·K) of a magnetic shielding can of a magnetic shielding structure with and without a thermalization surface treatment as a function of temperature in Kelvin. The magnetic shielding can include a NiFe alloy with a thickness of about 1 mm; and the thermalization surface treatment includes plating a thin layer of Cu followed by a thin layer of Au. The Cu—Au bilayer thermalization treatment coating has a thickness of 50 μm. As shown in FIG. 4A, the Cu—Au surface treated NiFe alloy shows an improved thermal conductivity compared to that of the bare NiFe alloy in the temperature range of 0-300 K.

FIG. 4B is a semi-log plot 410 showing the temperature in Kelvin of the magnetic shielding can with and without the thermalization treatment as a function of time during a simulated cooling process. As shown in FIG. 4A, the Cu—Au surface treatment layer can improve the thermal conductivity of the NiFe alloy, thus the thermalization rate of the magnetic shielding can. As shown in FIG. 4B, the time required to cool down the surface-treated magnetic shielding can is reduced from more than 7 days to less than 5 days.

FIG. 4C is a plot 420 showing the temperature of a circuit board in the surface-treated magnetic shielding can as a function of time during the simulated cooling process. As shown in FIG. 4C, the circuit board can be cooled down in about less than half a day, much faster than the time required for cooling the magnetic shielding cans shown in FIG. 4B. This shows that the temperature of the quantum processing unit can reach the base temperature of the refrigeration system at least as fast as the rest of the refrigerator.

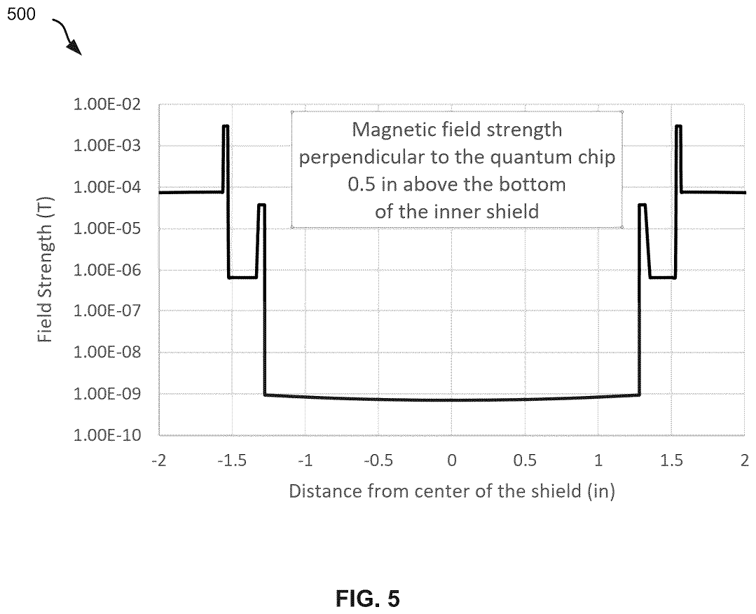

FIG. 5 is a plot 500 showing the magnetic field strength in Tesla (T) as a function of distance from the center of the magnetic shielding cans (in). As shown in FIG. 5, the magnetic shielding with the Cu—Au treated NiFe alloy is effective in isolating the external magnetic field. The background field is assumed to be about 0.5 gauss (G) or 5e-4 T. The simulation shows that a shielding factor of more than 1e5 is expected at the location of the quantum processing unit on the circuit board 302.

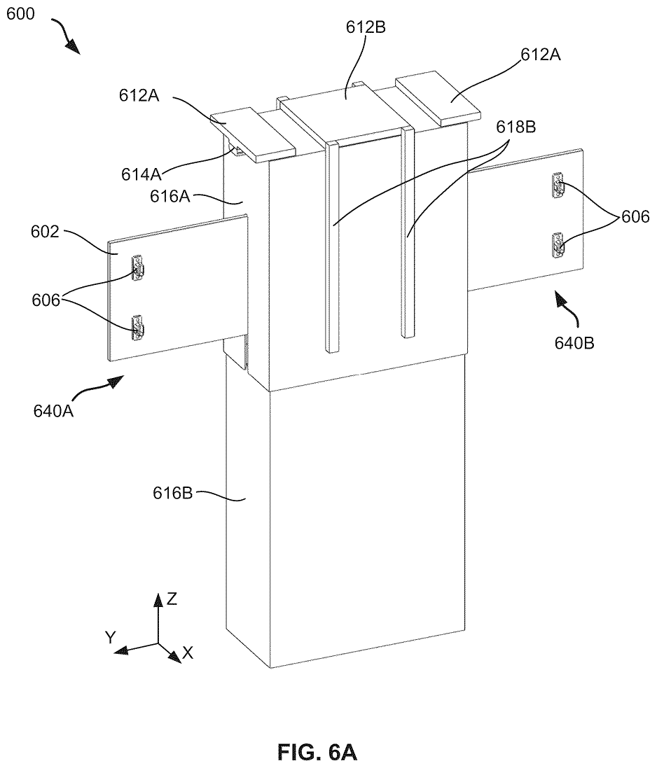

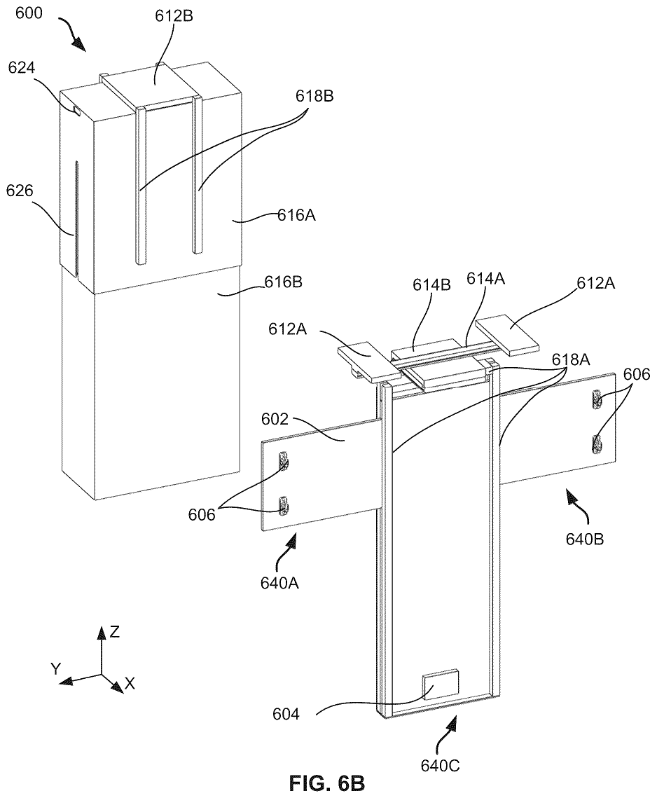

FIGS. 6A-6B include schematic diagrams showing perspective views of an example assembly 600. As shown in FIGS. 6A-6B, the example assembly 600 includes a circuit board 602, a quantum processing unit 604, a magnetic shielding structure 616, and thermalization frames 618A, 618B, and interleaved circuit board brackets 614A, 614B, 614C. The magnetic shielding structure 616 defines an interior volume to contain at least one component of the quantum processing unit 604 residing on a circuit board 602. The magnetic shielding structure 616 includes magnetic shielding cans 616A, 616B. The example assembly 600 may include additional or different features, and the components of the example assembly 600 may be configured as described with respect to FIGS. 6A-6B or in another manner.

As shown in FIGS. 6A-6B, a first end portion 640A and a second end portion 640B of the circuit board 602 include electrical connectors 606 that are configured to interface with communication links (e.g., electrical cables). In some instances, the electrical connectors 606 may be configured to interface with flat circuit cables, flat printed circuit cables, or other types of flex cables. In some instances, the electrical connectors 606 may be flat circuit connectors or other types of electrical connectors.

In some implementations, the circuit board 602 includes electrical circuitry configured to communicate electrical signals between the electrical connectors 606 on the first and second end portions 640A, 640B of the circuit board 602 and the quantum processor 604 at a central portion 640C of the circuit board 602. In some implementations, the electrical circuitry includes signal lines extending from the first end portion 640A and the second end portion 640B, through the central portion 640C, into the quantum processing unit 604. In some instances, the circuit board 602 may be implemented as the circuit board 302 shown in FIGS. 3A-3D or in another manner.

After assembly, the circuit board 602 protrudes continuously through the magnetic shielding can 616A from the outside to the inside of the magnetic shielding can 616A. As shown in FIGS. 6A-6B, the first and second end portions of the circuit board 640A, 640B reside outside the magnetic shielding structure 616, while the central portion 640C reside in an interior volume defined by the magnetic shielding can structure 616. In some instances, the magnetic shielding structure 616 may include two or more pairs of magnetic shielding cans being configured one inside another and providing two or more layers of magnetic shielding to reject or absorb external magnetic field along the X-axis and Y-axis perpendicular to the Z-axis of the assembly 600. In some instances, the magnetic shielding cans 616A, 618B of the example assembly 600 may be configured as the one shown in FIGS. 3A-3D or in another manner. In some implementations, the components of the quantum processing unit 604 residing at the central portion 640C of the circuit board 602 and inside the magnetic shielding cans 616A, 616B of the assembly 600 includes a superconducting quantum circuit, which can be implemented as the quantum processing unit 304 in FIGS. 3A-3D.

As shown in FIGS. 6A-6B, the circuit board 602 and the magnetic shielding cans 616A, 616B are effectively thermalized to a common thermalization stage (e.g., a thermalization stage of a cryostat, e.g., the lowest-temperature thermalization stage 214C of the cryostat 200 in FIG. 2, or another thermalization stage) via two separate thermalization pathways. In particular, the surfaces of the circuit board 602 are thermalized to the first top plates 612A via a first set of thermalization frames 618A and the interleaved circuit board brackets 614A, 614B such that heat generated on the circuit board 602 can be dissipated to the thermalization stage via the first set of thermalization frames 618A, the interleaved circuit board brackets 614A, 614B, and the first top plates 612A. In other words, the first set of thermalization frames 618A and the interleaved circuit board brackets 614A, 614B provide thermal contact between the first top plate 612A and the circuit board 602. Similarly, both the inner and outer surfaces of the magnetic shielding cans 616A, 616B are thermalized to the second top plate 612B via a second set of thermalization frames 618B. In some implementations, the second set of thermalization frames 618B contacts both inner and outer surfaces of all magnetic shielding cans 616A, 616B. In other words, the second set of thermalization frames 618B provides thermal contact between the second top plate 612B and the magnetic shielding cans 616A, 616B. The first and second top plates 612A, 612B are in thermal contact with the common thermalization stage.

In some instances, the circuit board 602 and the magnetic shielding cans 616A,616B may be separately thermalized to the thermalization stage via more than two thermalization pathways. For example, when the magnetic shielding structure 616 includes multiple layers of magnetic shielding cans, separate sets of thermalization frames may be configured such that the magnetic shielding cans may be thermalized to the thermalization stage through separate thermalization pathways. For another example, the circuit board 602 may be mechanically supported on and thermalized to multiple separate thermalization frames and respective top plates which are attached to the thermalization stage. In other words, the example assembly 600 may include at least one first thermalization pathway for the circuit board 602, and at least one second, distinct thermalization pathway for the magnetic shielding cans 616A, 616B. In some instances, the assembly 600 includes thermalization pathways for other components of the assembly 600; the thermalization pathways may be formed by different components; and components forming the thermalization pathways may be connected in another manner.

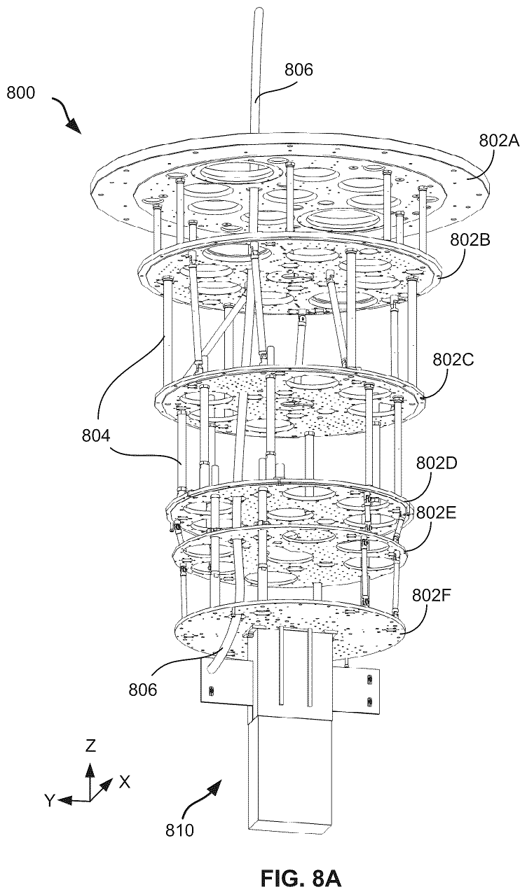

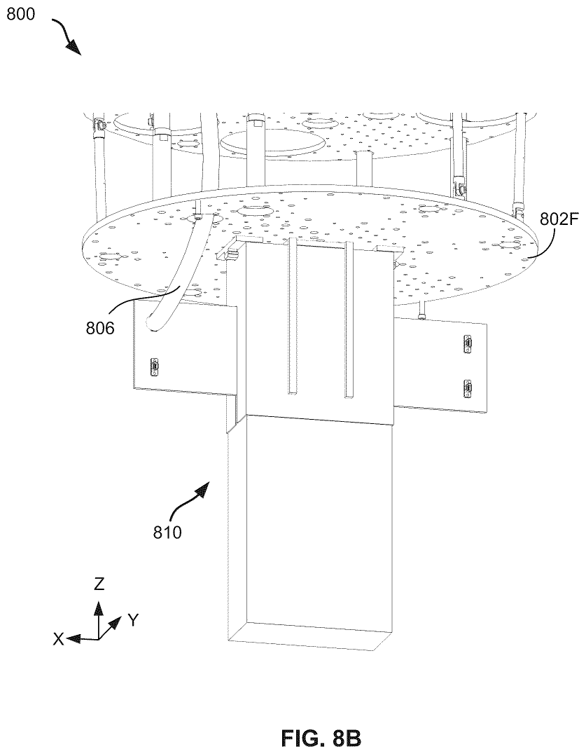

In some instances, the interleaved circuit board brackets 614A, 614B and the top plates 612A are fastened to one another in a sequence, for example, using fasteners through alignment holes in the interleaved circuit board brackets 614A, 614B or in another manner, such that the interleaved circuit board brackets 614A, 614B are effectively thermalized to one another. In some instances, the interleaved circuit boards 614A, 614B are also interleaved with the magnetic shielding cans 616A through respective holes 624 such that the magnetic shielding cans 616A are mechanically mounted and suspended on the first top plates 612A. In some instances, the second set of thermalization frames 618B is configured to mechanically mount the magnetic shielding cans 616A, 616B and thermalize them to the second top plate 612B. In some implementations, the interleaved circuit board brackets 614A, 614B, the thermalization frames 618A, 618B, and the top plates 612A, 612B contain materials that have high thermal conductivity which allows heat dissipation from the circuit board 602 and the magnetic shielding cans 616A, 616B to the thermalization stage (e.g., the lowest-temperature thermalization stage 212C in FIG. 2). In some instances, the interleaved circuit board brackets 614A, 614B, the thermalization frames 618A, 618B, and the top plates 612A, 612B may be made of the same material as the thermalization stage. In some instances, both the inner and outer surfaces of each of the magnetic shielding cans 616A, 616B may be treated to improve the thermal conductivity of the magnetic shielding cans 616A, 616B while maintaining their effectiveness in magnetic shielding. For example, the magnetic shielding cans 616A, 616B may be implemented as the magnetic shielding cans 316A, 316B in FIGS. 3A-3D or in another manner. In some implementations, the top plates 612A, 612B are mechanically supported and thermally anchored to a lowest-temperature thermalization stage (e.g., the lowest-temperature thermalization stage 212C, 802F as shown in FIGS. 2, 8A-8B) for heat dissipation.

In some implementations, the circuit board 602 is mechanically in contact with and thermalized to the interleaved circuit board brackets 614A, 614B and the first set of thermalization frames 618A. A slot 626 on the magnetic shielding 616A has a geometric dimension that is large enough to separate the circuit board 602 from direct contact with the magnetic shielding cans 616A preventing the formation of a thermal link. In some implementations, the systems and techniques presented here allow the circuit board 602 to cool down to a temperature below 10 mK in about 60 hrs; and the cooling rate of the circuit board 602 is limited primarily by the cooling rate of the thermalization stage.

In some instances, the assembly 600 may be configured on the thermalization stage as shown in FIG. 2 with the extending directions of the circuit board 602 and the magnetic shielding cans 616A, 616B perpendicular to the surface of the thermalization stage (e.g., along the Z direction). In certain instances, the first and second sets of thermalization frames 618A, 618B and the interleaved circuit board brackets 614A, 614B could be shaped in an angle (e.g., with an elbow shape or another shape) which allows the extending directions of the circuit board 602 and the magnetic shielding cans 616A, 616B parallel to the surface of the thermalization stage (e.g., along the X-Y plane). In some instances, the first and second sets of thermalization frames 618A, 618B and the interleaved circuit board brackets 614A, 614B may be configured or shaped such that the magnetic shielding cans 616A, 616B and the circuit board 602 are oriented in any angle relative to the respective top plates 612A, 612B and thus the thermalization stage.

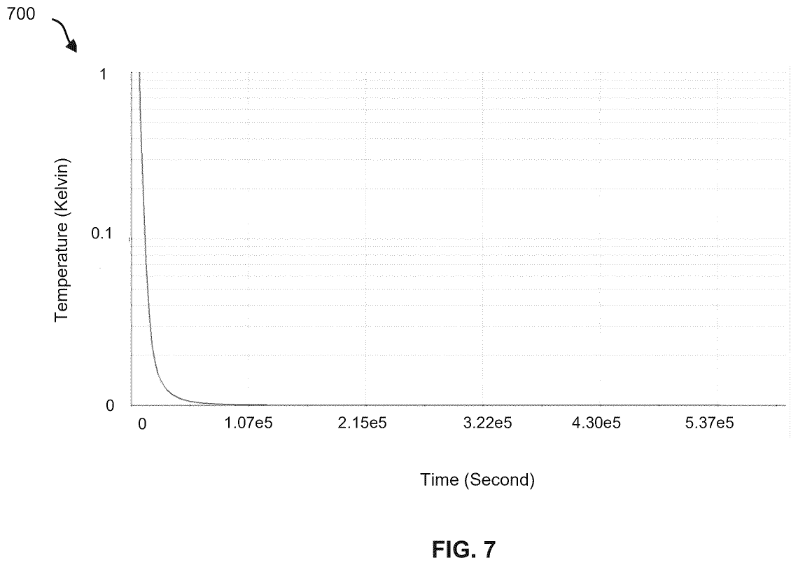

FIG. 7 is a plot 700 showing the temperature of a QPU puck for holding components of a quantum processing unit on a circuit board in an example apparatus as a function of time during a simulated cooling process. The example apparatus includes separated thermalization pathways for the circuit board and a magnetic shielding structure. In the simulation, the QPU puck is a copper device used to hold the QPU to the circuit board. As shown in FIG. 7, the temperature of the QPU puck can be cooled down to below 10 mK in about 60 hours, much faster than the time required for cooling an apparatus with a shared thermalization pathway for the circuit board and the magnetic shielding structure. In the simulation, the initial temperature is configured at 300 K with a cooling power at 0.01 K at the thermalization stage contact. The simulation was performed using temperature dependent thermal conductivity parameters for both copper and A4K shields shown in FIG. 4A. The transient thermal study increments were set to a higher resolution to be able to compare the response of the separated thermalization pathways.

FIGS. 8A-8B include diagrams showing aspects of an example cryostat 800 of a quantum computing system. As shown in FIGS. 8A-8B, the example cryostat 800 includes multiple thermalization stages 802A, 802B, 802C, 802D, 802E, 802F in a dilution refrigerator system. In some instances, the dilution refrigerator system of the cryostat 800 may be implemented and operated as the dilution refrigerator system 224 shown in FIG. 2 or in another manner. In some implementations, the example cryostat 800 may be used to expose devices and samples to environments of very low temperature (e.g., T<120 K). In some implementations, vacuum cryostats are used for thermal isolation, typically having a pressure in the range of 0.1 to 10⁻⁷ Pascal, thereby allowing the example cryostat 800 to operate at stable temperatures without appreciable thermal losses.

In some implementations, the one or more thermalization stages 802A, 802B, 802C, 802D, 802E, 802F may correspond to radiation shields, thermalization plates, or both. In some instances, a thermalization stage 802A, 802B, 802C, 802D, 802E, 802F in the example cryostat 800 may be implemented and operated as the thermalization stage 212 of the example cryostat 200 shown in FIG. 2 or in another manner. The example cryostat 800 may include any number of thermalization stages 802 to support subsystems, devices, and samples for cryogenic refrigeration. FIG. 8A depicts six thermalization stages 802 in a linear sequence. In some implementations, the example cryostat 800 may include any number and spacing of thermalization stages 802 as needed. In the example shown in FIGS. 8A-8B, the example cryostat 800 includes one or more structural supports 804 to position the thermalization stages 802 into the spatial sequence of thermalization stages. In some examples, the structural supports 804 may be implemented and operated as the structure support 212 of the example cryostat 200 shown in FIG. 2 or in another manner.

In some implementations, the example cryostat 800 may also include one or more refrigeration systems (not shown) thermally coupled to each of the thermalization stages 802. For example, the example cryostat 800 may include a pulse-tube refrigeration system coupled to a second lowest-temperature thermalization stage 802E and a ³He/⁴He dilution refrigerator system thermally coupled to a lowest-temperature thermalization stage 802F. The example cryostat 800 establishes specific operating temperatures for the thermalization stages 802 to which they are respectively thermally coupled. In some implementations, the example cryostat 800 may define a distribution of operating temperatures along the spatial sequence of thermalization stages 802. In some implementations, a pulse-tube refrigeration unit may be configured to optimally extract heat at temperatures to about 4 K and a ³He/⁴He dilution refrigerator unit may be configured to optimally extract heat at temperatures below 1 K.

In some implementations, the example cryostat 800 includes an assembly 810 mechanically supported on a thermalization stage. As shown in FIGS. 8A-8B, the assembly 810 is configured on the lowest-temperature thermalization stage 802F. In some implementations, the example assembly 810 includes a magnetic shielding structure which defines an interior volume that contains at least one component of a quantum processing unit. The magnetic shielding structure includes one or more magnetic shielding cans. In some implementations, the magnetic shielding structure of the assembly 810 can be configured to create a barrier that blocks or redirects magnetic fields from at least a portion of the circuit board where a quantum processing unit is supported. In particular, the magnetic shielding cans of the assembly 810 can effectively shield components of the quantum processing unit from magnetic fields that are perpendicular to the surface of the circuit board. In some instances, the magnetic shielding structure includes materials that have high levels of magnetic permeability, e.g., nickel-iron (Ni—Fe) alloy, nickel-molybdenum (Ni—Mo), ferrite, superconductive materials, amorphous metal, conductive polymer, or other types of materials. As shown in FIGS. 8A-8B, the assembly 810 extends along the Z-axis perpendicular to the surface of the lowest-temperature thermalization stage 802F which is in the X-Y plane. In some instances, the assembly 810 may be oriented relative to the lowest-temperature thermalization stage 802F or other thermalization stages of the cryostat 800 in a different manner.

In some implementations, the surfaces of the magnetic shielding structure of the assembly 810 are treated to improve their thermal conductivity properties. For example, the surfaces of the magnetic shielding structure may include a thermalization coating on both inner and outer surfaces to improve the thermal conductivity of the magnetic shielding structure. In some instances, the thermalization coating to improve the thermal conductivity of the magnetic shielding structure includes a thermally conductive material such as metal, metal superlattice, metal alloy, metal oxide, ceramic, or another type of material. In some instances, the surface treatment approach used to improve the thermal conductivity of the magnetic shielding structure does not degrade their magnetic shielding effectiveness. In some instances, the thermal conductivity of the magnetic shielding structure of the assembly 810 may be improved in another manner.

In some instances, the circuit board and the surface-treated magnetic shielding structure of the assembly 810 are independently mechanically supported and thermally anchored to the lowest-temperature thermalization stage 802F. In other words, heat generated in the circuit board can be dissipated to the lowest-temperature thermalization stage 802F via a first thermalization pathway; and the magnetic shielding structure can be separately thermalized to the lowest-temperature thermalization stage 802F via a second, distinct thermalization pathway. Each of the first and second thermalization pathways provided by the assembly 810 includes a distinct set of mechanically connected components, e.g., interleaved circuit board brackets, thermalization frames, and top plates. Each of the first and second thermalization pathways provide thermal contact between the magnetic shielding structure or the circuit board to the lowest-temperature thermalization stage 802F. Heat from the magnetic shielding structure is dissipated to reduce heat radiation to the quantum processing unit residing inside the magnetic shielding structure. In some implementations, the circuit board may be implemented as the circuit board 602; and the surface-treated magnetic shielding structure can be implemented as the magnetic shielding cans 616A, 616B shown in FIGS. 6A-6B or in another manner. In some implementations, the assembly 810 can provide technical advantages. The assembly 810 can improve the performance of the quantum processing unit and reduce the cooling time of the system. In some instances, the cooldown rate of the magnetic shielding structure through the thermalization frame is on the order of several days, allowing for any radiation from them to be limited to this time period, which is on the order of the time that the entire system takes to cool down.

In some implementations, the assembly 810 can be implemented as the assembly 600 shown in FIGS. 6A-6B, which has a rectangular prism shape. In some instances, the assembly 810 may be implemented in another manner. For example, the assembly 810 may have a different three-dimensional geometric shape, e.g., rectangular prism with rounded corners, cylindrical, sphere, ovoid, ellipsoid, cone, irregular, or another three-dimensional geometric shape.

In some implementations, the quantum processing unit on the circuit board enclosed in the magnetic shielding structure of the assembly 810 may receive and transmit signals via transmission links 806. The transmission links 806 can transmit control signals to the quantum processing unit, and readout signals from the quantum processing unit out of the dilution refrigerator system of the cryostat 800. In some instances, the signals communicated on the transmission links 806 are microwave-frequency signals, radiofrequency signals, or other types of communication signals. As shown in FIGS. 8A-8B, the transmission links 806 in the dilution refrigerator system are configured separately from the structural supports 804 through the thermalization stages 802. In certain instances, the transmission links 804 may be arranged or routed in another manner to couple signal hardware in the control system outside of the cryostat 800 (e.g., the signal hardware 104 in the control system 105 in FIG. 1).

In some instances, the circuit board and the magnetic shielding structure are independently mounted to the lowest-temperature thermalization stage 802F in a way that there is no line of sight through the penetrations. In some instances, the circuit board extends (along the Y-Z plane) continuously through slots along a first direction on the magnetic shielding structure such that a first end portion of the circuit board resides outside the slots of the magnetic shielding structure; a second opposite end portion of the circuit board residing outside the slots of the magnetic shielding structure, and a central portion of the circuit board resides in the magnetic shielding structure. The central portion of the circuit board also extends inside the magnetic shielding structure in a second, distinct direction, which may be normal to the first direction (along the Z-axis). The quantum processing unit residing on the extended central portion of the circuit board is away from the slots where the circuit board protrudes the magnetic shielding structure. In some instances, this configuration may allow the minimization or reduction of the effect of magnetic fields leaking into the magnetic shielding structure through the slots on the quantum processing unit. In some implementations, the circuit board is a printed circuit board, or another type of circuit board. In some implementations, the circuit board may be configured in another manner. For example, the circuit board may have a different shape. For another example, the circuit board may be completely enclosed by the magnetic shielding structure; and in this case, the magnetic shielding structure may include fittings, connections, or other parts that allow communication links 806 to communicate with the circuit board inside the magnetic shielding structure.

In some instances, the circuit board includes impedance-matched lines for RF signals, low resistance lines for DC signals, or other types of signal lines allowing for high-density RF- and DC-signals passing through electrical connectors to the quantum processing unit. In some examples, the circuit board may be a multilayered circuit board with multiple metallization layers; may include an array of electrically and thermally conductive through hole vias; and may include additional or different features. In some instances, the circuit board includes superconducting materials to allow for lower electrical resistance operations at cryogenic environment without significantly increasing the thermal conductance.

In some implementations, the circuit board may include two or more quantum processing units; and each quantum processing unit includes qubit devices and other quantum circuit devices in a range of 40 to 100 devices, for example. This approach can be scaled such that the quantum processing units integrated on the circuit board can operate up to ˜10,000 or more qubit devices. The circuit board with a high density of signal lines (e.g., in a range of greater than or equal to 0.2 signals/mm² or another range) can be used for communicating electrical signals (e.g., control signals and readout signals) between the quantum circuit devices of the quantum processing units in the assembly 810 with a control system outside of the cryostat 800 through the communication links 806.

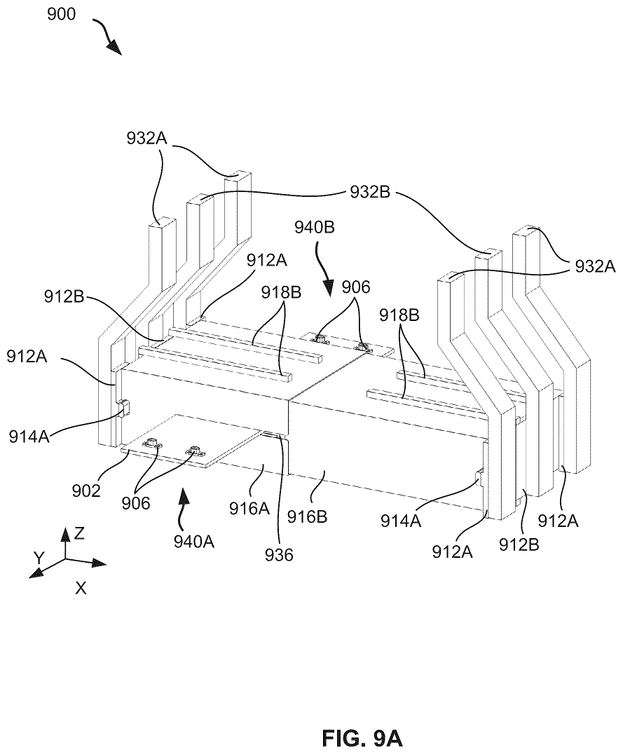

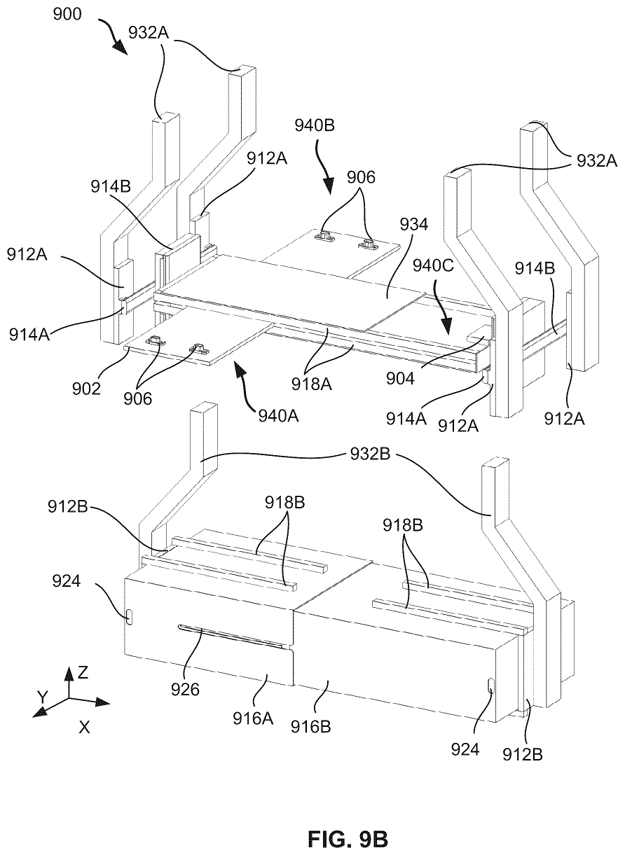

FIGS. 9A-9B include diagrams showing perspective views of an example assembly 900. As shown in FIGS. 9A-9B, the example assembly 900 includes a magnetic shielding structure 916, thermalization frames 918B, 918B, end plates 912A, 912B, and hanging bars 932A, 932B. The magnetic shielding structure 916 defines an interior volume that contains at least one component of a quantum processing unit 904. The magnetic shielding structure 916 includes two layers of magnetic shielding cans 916A, 916B. The example assembly 900 may include additional or different features, and the components of the example assembly 900 may be configured as described with respect to FIGS. 9A-9B or in another manner.

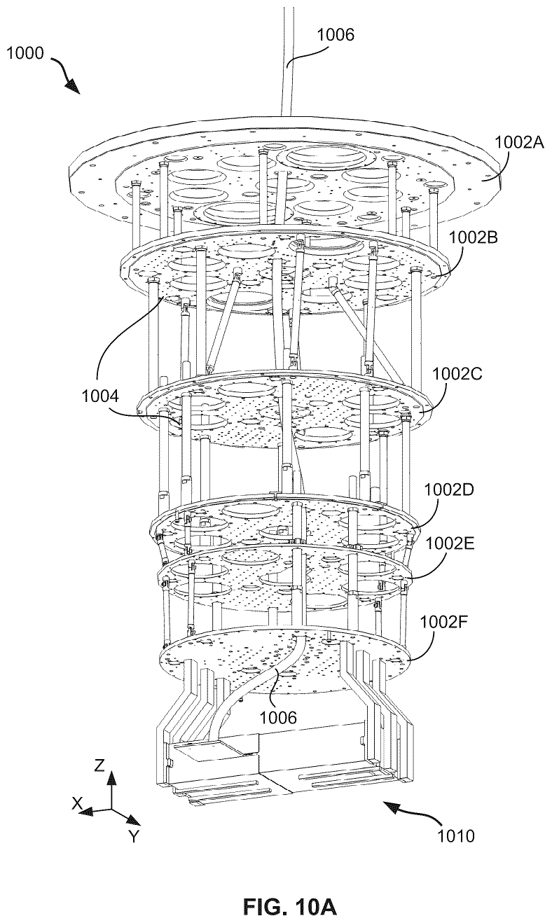

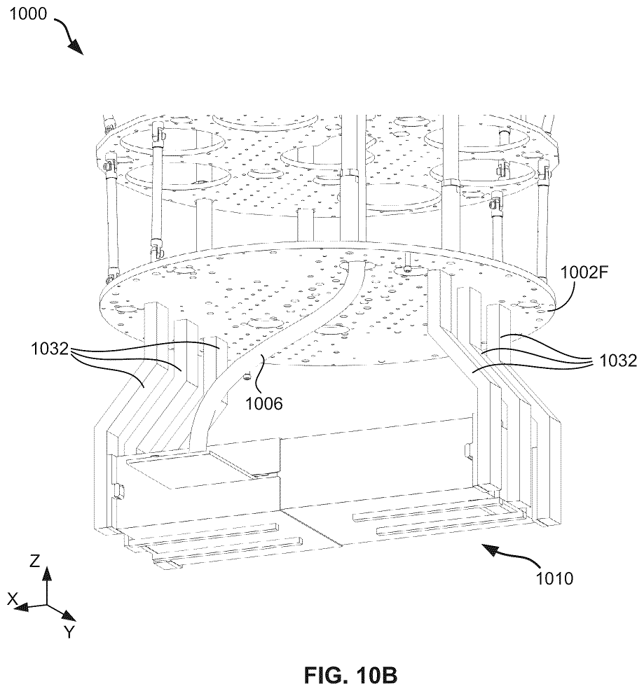

The circuit board 902 is positioned on the assembly 900. As shown in FIGS. 9A-9B, a first end portion 940A and a second end portion 940B of the circuit board 902 include electrical connectors 906 that are configured to interface with communication links (e.g., the communication links 1004 in FIGS. 10A-10B). In some instances, the electrical connectors 906 may be configured to interface with flat circuit cables, flat printed circuit cables, or other types of flex cables. In some instances, the electrical connectors 906 may be flat circuit connectors or other types of electrical connectors.

In some implementations, the circuit board 902 includes electrical circuitry configured to communicate electrical signals between the electrical connectors 906 on the first and second end portions 940A, 940B of the circuit board 902 and the quantum processor 904 at a central portion 940C of the circuit board 902. In some implementations, the electrical circuitry includes signal lines extending from the first end portion 940A and the second end portion 940B, through the central portion 940C, into the quantum processing unit 904. In some instances, the circuit board 902 may be implemented as the circuit board 302, 602 shown in FIGS. 3A-3D, 6A-6B, or in another manner.

After positioning, the circuit board 902 protrudes continuously through the magnetic shielding can 916A from the outside to the inside of the magnetic shielding can 916A. As shown in FIGS. 9A-9B, the first and second end portions 940A, 940B of the circuit board 902 reside outside the magnetic shielding cans 916, while the central portion 640C reside in the magnetic shielding can 916A/916B. In some instances, the example assembly 900 may include two or more pairs of magnetic shielding cans 916 being configured one inside another and providing two or more layers of magnetic shielding to reject or absorb external magnetic field along the X-axis and Y-axis perpendicular to the Z-axis of the assembly 900. In some instances, the magnetic shielding cans 916A, 918B of the example assembly 900 may be configured as the magnetic shielding cans 616A, 618B shown in FIGS. 6A-6B or in another manner. In some implementations, at least a component of the quantum processing unit 904 includes a superconducting quantum circuit, which resides at the central portion 940C of the circuit board 902 and inside the magnetic shielding cans 916A, 916B of the assembly 900. The quantum processing unit 904 may be implemented as the quantum processing unit 304, 604, in FIGS. 3A-3D, 6A-6B.

As shown in FIGS. 9A-9B, the circuit board 902 and the magnetic shielding cans 916A, 916B are effectively thermalized to a common thermalization stage (e.g., a thermalization stage of a cryostat, e.g., the lowest-temperature thermalization stage 214C, 1002F of the cryostat 200, 1000 in FIGS. 2, 10A-10B, or another thermalization stage) via two separate thermalization pathways. In particular, the surfaces of the circuit board 902 are thermalized to a first set of end plates 912A via a first set of thermalization frames 918A and the interleaved circuit board brackets 914A, 914B such that heat generated on the circuit board 902 can be dissipated to the thermalization stage via the first set of thermalization frames 918A, the interleaved circuit board brackets 914A, 914B, and the first set of end plates 912A. Similarly, both the inner and outer surfaces of the magnetic shielding cans 916A, 916B are thermalized to a second set of end plates 912B via a second set of thermalization frames 918B and a second set of end plates 912B. In some implementations, the second set of thermalization frames 918B contacts both inner and outer surfaces of all magnetic shielding cans 916A, 916B. In some implementations, the first and second sets of end plates 912A, 912B are in thermal contact with the common thermalization stage. In some implementations, the first set of thermalization frames 918A, the interleaved circuit board brackets 914A, 914B, and the first set of end plates 912A provide thermal contact between the circuit board 902 and the common thermalization stage. In some implementations, the second set of thermalization frames 918B and the second set of end plates 912B provide thermal contact between the magnetic shielding cans 916A, 916B and the common thermalization stage.

In some implementations, the circuit board 902 and the magnetic shielding cans 916A, 916B are separately thermalized to the thermalization stage via more than two thermalization pathways. For example, when the assembly 900 includes multiple layers of magnetic shielding cans, separate sets of thermalization frames may be configured such that the magnetic shielding cans may be thermalized to the thermalization stage through separate thermalization pathways. For another example, the circuit board 902 may be mechanically supported on and thermalized to multiple separate thermalization frames and respective end plates which are attached to the thermalization stage. In other words, the example assembly 900 may include at least one first thermalization pathway for the circuit board 902, and at least one second, distinct thermalization pathway for the magnetic shielding cans 916A, 916B. In some instances, the assembly 900 includes thermalization pathways for other components of the assembly 900; the thermalization pathways may be formed by different components; and components forming the thermalization pathways may be connected in another manner.

In some instances, the interleaved circuit board brackets 914A, 914B and the first set of end plates 912A are fastened to one another in a sequence, for example, using fasteners through alignment holes in the interleaved circuit board brackets 914A, 914B or in another manner, such that the interleaved circuit board brackets 914A, 914B are effectively thermalized to one another. In some instances, the interleaved circuit boards 914A, 914B are also interleaved with the magnetic shielding can 916A through respective holes 924 such that the magnetic shielding can 916A are mechanically mounted and suspended on the first set of end plates 912A. In some instances, the second set of thermalization frames 918B is configured to mechanically mount the magnetic shielding cans 916A, 916B and thermalize them to the second set of end plates 912B. In some implementations, the interleaved circuit board brackets 914A, 914B, the thermalization frames 918A, 918B, and the first and second sets of end plates 912A, 912B contain materials that have high thermal conductivity which allows heat dissipation from the circuit board 902 and the magnetic shielding cans 916A, 916B to the thermalization stage (e.g., the lowest-temperature thermalization stage 212C, 1002F in FIGS. 2, 10A-10B). In some instances, the interleaved circuit board brackets 914A, 914B, the thermalization frames 918A, 918B, and the first and second sets of end plates 912A, 912B may be made of the same material as the thermalization stage. In some instances, both the inner and outer surfaces of each of the magnetic shielding cans 916A, 916B may be treated to improve the thermal conductivity of the magnetic shielding cans 916A, 916B while maintaining their effectiveness in magnetic shielding. In some implementations, the first set of end plates 912A are mechanically supported and thermally anchored to a lowest-temperature thermalization stage (e.g., the lowest-temperature thermalization stage 212C, 1002F as shown in FIGS. 2, 10A-10B) via a first set of hanging bars 932A; and the second set of end plates 912B are mechanically supported an thermally anchored to the lowest-temperature thermalization stage via a second set of hanging bars 932B.

In some implementations, the circuit board 902 is mechanically in contact with and thermalized to the interleaved circuit board brackets 914A, 914B and the first set of thermalization frames 918A. A slot 936 on the magnetic shielding can 916A has a geometric dimension that is large enough to separate the circuit board 902 from direct contact with the magnetic shielding can 916A preventing the formation of a thermal link. In some implementations, the systems and techniques presented here allow the circuit board 902 to cool down to a temperature below 10 mK in about 60 hrs; and the cooling rate of the circuit board 902 is limited primarily by the cooling rate of the thermalization stage.

In some instances, the assembly 900 may be configured on the thermalization stage as shown in FIGS. 10A-10B with the extending directions of the circuit board 902 and the magnetic shielding cans 916A, 916B parallel to the surface of the thermalization stage (e.g., along the XY plane). In certain instances, the first and second sets of thermalization frames 918A, 918B and the interleaved circuit board brackets 914A, 914B could be shaped in an angle (e.g., with an elbow shape or another shape) which allows the extending directions of the circuit board 902 and the magnetic shielding cans 916A, 916B in any angle relative to the thermalization stage.

FIGS. 10A-10B include diagrams showing aspects an example cryostat 1000 of a quantum computing system. As shown in FIGS. 10A-10B, the example cryostat 1000 includes multiple thermalization stages 1002A, 1002B, 1002C, 1002D, 1002E, 1002F in a dilution refrigerator system. In some instances, the dilution refrigerator system of the cryostat 1000 may be implemented and operated as the dilution refrigerator system 224 shown in FIG. 2 or in another manner. In some implementations, the example cryostat 1000 may be used to expose devices and samples to environments of very low temperature (e.g., T<120 K). In some implementations, vacuum cryostats are used for thermal isolation, typically having a pressure in the range of 0.1 to 10⁻⁷ Pascal, thereby allowing the example cryostat 800 to operate at stable temperatures without appreciable thermal losses.

In some implementations, the one or more thermalization stages 1002A, 1002B, 1002C, 1002D, 1002E, 1002F may correspond to radiation shields, thermalization plates, or both. In some instances, a thermalization stage 1002A, 1002B, 1002C, 1002D, 1002E, 1002F in the example cryostat 1000 may be implemented and operated as the thermalization stage 212, 802 of the example cryostats 200, 800 shown in FIGS. 2, 8A-8B, or in another manner. The example cryostat 1000 may include any number of thermalization stages 1002 to support subsystems, devices, and samples for cryogenic refrigeration. FIG. 10A depicts six thermalization stages 1002 in a linear sequence. In some implementations, the example cryostat 1000 may include any number and spacing of thermalization stages 1002 as needed. In the example shown in FIGS. 10A-10B, the example cryostat 1000 includes one or more structural supports 1004 to position the thermalization stages 1002 into the spatial sequence of thermalization stages. In some examples, the structural supports 1004 may be implemented and operated as the structure support 212, 804 of the example cryostats 200, 800 shown in FIGS. 2, 8A-8B, or in another manner.

In some implementations, the example cryostat 1000 may also include one or more refrigeration systems (not shown) thermally coupled to each of the thermalization stages 1002. For example, the example cryostat 1000 may include a pulse-tube refrigeration system coupled to a second lowest-temperature thermalization stage 1002E and a ³He/⁴He dilution refrigerator system thermally coupled to a lowest-temperature thermalization stage 1002F. The example cryostat 1000 establishes specific operating temperatures for the thermalization stages 1002 to which they are respectively thermally coupled. In some implementations, the example cryostat 1000 may define a distribution of operating temperatures along the spatial sequence of thermalization stages 1002. In some implementations, a pulse-tube refrigeration unit may be configured to optimally extract heat at temperatures to about 4 K and a ³He/⁴He dilution refrigerator unit may be configured to optimally extract heat at temperatures below 1 K.

In some implementations, the example cryostat 1000 includes an assembly 1010 mechanically supported on a thermalization stage. As shown in FIGS. 10A-10B, the assembly 1010 is configured on the lowest-temperature thermalization stage 1002F. In some implementations, the example assembly 1010 includes a magnetic shielding structure. The example assembly 1010 holds a circuit board. In some instances, the assembly 1010 may be implemented as the example assembly 900 shown in FIGS. 9A-9B. As shown in FIGS. 10A-10B, the assembly 1010 extends along the XY plane parallel to the surface of the lowest-temperature thermalization stage 1002F. In some instances, the assembly 1010 may be oriented relative to the lowest-temperature thermalization stage 1002F or other thermalization stages of the cryostat 1000 in a different manner.

In some instances, the circuit board hold by the assembly 1010 and the surface-treated magnetic shielding structure of the assembly 1010 are independently mechanically supported and thermally anchored to the lowest-temperature thermalization stage 1002F. In other words, heat generated in the circuit board can be dissipated to the lowest-temperature thermalization stage 1002F via a first thermalization pathway; and the magnetic shielding structure can be separately thermalized to the lowest-temperature thermalization stage 1002F via a second, distinct thermalization pathway. Each of the first and second thermalization pathways provided by the assembly 1010 includes a distinct set of hardware components, e.g., interleaved circuit board brackets, thermalization frames, end plates, and hanging bars. Specifically, referring to the example assembly 900 shown in FIGS. 9A-9B, the first thermalization pathway for the circuit board is enabled by the first set of thermalization frames 918A, the interleaved circuit board brackets 914A, 914B, the first set of end plates 912A, and the first set of hanging bars 932A; and the second thermalization pathway for the magnetic shielding structure is enabled by the second set of thermalization frames 918B, the second set of end plates 912B, and the second set of hanging bars 932B. In other words, the first thermalization pathway provides thermal contact between the circuit board and the thermalization stage; and the second thermalization pathway provides thermal contact between the magnetic shielding structure and the thermalization stage. Heat from the magnetic shielding cans is dissipated to reduce heat radiation to the components of the quantum processing unit residing at the interior volume defined by the magnetic shielding structure. In some implementations, the circuit board may be implemented as the circuit board 602; and the surface-treated magnetic shielding structure can be implemented as the magnetic shielding cans 616A, 616B shown in FIGS. 6A-6B or in another manner. In some implementations, the assembly 1010 can provide technical advantages. The assembly 1010 can improve the performance of the quantum processing unit and reduce the cooling time of the system. In some instances, the cooldown rate of the magnetic shielding structure through the thermalization frame is on the order of several days, allowing for any radiation from them to be limited to this time period, which is on the order of the time that the entire system takes to cool down.

In some implementations, the assembly 1010 can be implemented as the assembly 900 shown in FIGS. 9A-9B, which has a rectangular prism shape. In some instances, the assembly 1010 may be implemented in another manner. For example, the assembly 1010 may have a different three-dimensional geometric shape, e.g., rectangular prism with rounded corners, cylindrical, sphere, ovoid, ellipsoid, cone, irregular, or another three-dimensional geometric shape.

In some implementations, at least one component of the quantum processing unit on the circuit board is enclosed in the magnetic shielding structure of the assembly 1010 may receive and transmit signals via transmission links 1006. In some instances, the transmission link 1006 may be implemented as the transmission link 806 in the example cryostat 800 shown in FIGS. 8A-8B or in another manner. In some instances, the circuit board and the magnetic shielding structure are independently mounted to the lowest-temperature thermalization stage 1002F in a way that there is no line of sight through the penetrations. In some instances, the mounting of the circuit board and the magnetic shielding structure in the example assembly 1010 may be implemented as the example shown in FIGS. 8A-8B or in another manner.

In a general aspect, magnetic shielding for a quantum processing unit is thermalized.

In a first example, an assembly to house a component of a quantum processing unit in a cryogenic environment, includes a plate, a magnetic shielding structure, a first thermalization pathway, and a second, independent thermalization pathway. The plate is configured to reside in thermal contact with a thermalization stage of a cryostat. The magnetic shielding structure defines an interior volume to contain a component of a quantum processing unit. The component resides on a circuit board. A first thermalization pathway provides thermal contact between the plate and the magnetic shielding structure. The second, independent thermalization pathway provides thermal contact between the plate and the circuit board.

Implementations of the first example may include one or more of the following features. The magnetic shielding structure includes a plurality of magnetic shielding cans. The first thermalization pathway includes a thermalization frame mounted to the magnetic shielding structure and configured to thermalize the magnetic shielding structure to the plate. The second thermalization pathway includes a set of interleaved circuit board brackets in thermal contact with the circuit board and configured to thermalize the circuit board to the plate. The thermalization stage is a lowest-temperature thermalization stage in the cryostat. The plate, the magnetic shielding structure, and the circuit board are thermalized to the lowest-temperature thermalization stage.

Implementations of the first example may include one or more of the following features. The component of the quantum processing unit resides on a central portion of the circuit board. The circuit board includes electrical circuitry extending from a first end portion to a second end portion via the central portion of the circuit board, and the electrical circuitry is configured to communicate signals with the component of the quantum processing unit. The magnetic shielding structure includes a plurality of magnetic shielding cans. The plurality of magnetic shielding cans include slots. The circuit board protrudes through the slots. The first and second end portions of the circuit board reside outside the plurality of magnetic shielding cans. The central portion of the circuit board reside inside the plurality of magnetic shielding cans. The apparatus includes a sealant material between the circuit board and edges of the slots. The sealant material prevents direct contact between the plurality of magnetic shielding cans and the circuit board. The component of the quantum processing unit includes at least a portion of a superconducting circuit. The superconducting circuit includes at least one of flux bias lines or microwave feedlines communicably coupled to the electrical circuitry of the circuit board.

Implementations of the first example may include one or more of the following features. The circuit board includes superconducting material. The plate includes a first segment and a second, distinct segment. The first thermalization pathway provides thermal contact between the first segment and the magnetic shielding structure. The second, independent thermalization pathway provides thermal contact between the second segment and the circuit board. The apparatus includes an infrared shielding can which is configured to protect the component of the quantum processing unit on the circuit board from infrared radiation.

Implementations of the first example may include one or more of the following features. The magnetic shielding structure includes magnetic material. Inner and outer surfaces of the magnetic shielding structure are coated with thermally conductive material. The magnetic material includes a nickel iron alloy and the thermal conductive material on the inner and outer surfaces of the magnetic shielding structure includes at least one layer of copper and at least one layer of gold. The plate is a first plate comprising a first segment and a second segment. The assembly includes a second plate comprising a third segment and a fourth segment. The first thermalization pathway provides thermal contact between the second and fourth segments and the magnetic shielding structure, and the second thermalization pathway provides thermal contact between the first and third segments and the circuit board.

In a second example, a method includes positioning a circuit board in an assembly in a cryostat. A component of a quantum processing unit resides on the circuit board. The assembly includes a magnetic shielding structure. The circuit board is positioned such that the component is housed within the magnetic shielding structure. The method includes thermalizing the magnetic shielding structure of the assembly to a thermalization stage of the cryostat via a first thermalization pathway defined by the assembly; and thermalizing the circuit board to the thermalization stage of the cryostat via a second, distinct thermalization pathway defined by the assembly.

Implementations of the second example may include one or more of the following features. The assembly includes a plate. The plate is in thermal contact with the thermalization stage of the cryostat. Thermalizing the magnetic shielding structure and the circuit board to the thermalization stage includes thermalizing the magnetic shielding structure and the circuit board to the plate. The first thermalization pathway includes a thermalization frame mounted to the magnetic shielding structure and configured to thermalize the magnetic shielding structure to the plate. The second thermalization pathway includes a set of interleaved circuit board brackets in thermal contact with the circuit board and configured to thermalize the circuit board to the plate. The thermalization stage is a lowest-temperature thermalization stage in the cryostat. Thermalizing the magnetic shielding structure and the circuit board includes thermalizing the magnetic shielding structure and the circuit board to the lowest-temperature thermalization stage. The plate includes a first segment and a second, distinct segment, the first thermalization pathway provides thermal contact between the first segment and the magnetic shielding structure, and the second, independent thermalization pathway provides thermal contact between the second segment and the circuit board. The plate is a first plate including a first segment and a second segment, the assembly includes a second plate including a third segment and a fourth segment, the first thermalization pathway provides thermal contact between the second and fourth segments and the magnetic shielding structure, and the second thermalization pathway provides thermal contact between the first and third segments and the circuit board.

Implementations of the second example may include one or more of the following features. The component of the quantum processing unit resides on a central portion of the circuit board. The circuit board includes electrical circuitry extending from a first end portion to a second end portion via the central portion of the circuit board, and the method includes communicating signals with the component of the quantum processing unit via the electrical circuitry. The magnetic shielding structure includes a plurality of magnetic shielding cans. The plurality of magnetic shielding cans include slots. Positioning the circuit board in the assembly includes positioning the circuit board in the assembly such that the circuit board protrudes through the slots, the first and second end portions of the circuit board reside outside the plurality of magnetic shielding cans, and the central portion of the circuit board reside inside the plurality of magnetic shielding cans.

Implementations of the second example may include one or more of the following features. The assembly includes a sealant material between the circuit board and edges of the slots. The sealant material prevents direct contact between the plurality of magnetic shielding cans and the circuit board. The component of the quantum processing unit includes a superconducting quantum circuit. The superconducting circuit includes at least one of flux bias lines or microwave feedlines communicably coupled to the electrical circuitry of the circuit board. Communicating signals with the component of the quantum processing unit includes communicating a flux bias control signal or a microwave control signal to the at least one of flux bias lines or the microwave feedlines.

The circuit board includes superconducting material. The assembly includes an infrared shielding can configured to protect the component of the quantum processing unit on the circuit board from infrared radiation. The magnetic shielding structure includes magnetic material, and inner and outer surfaces of the magnetic shielding structure are coated with thermally conductive material. The magnetic material includes a nickel iron alloy and the thermal conductive material on the inner and outer surfaces of the magnetic shielding structure includes at least one layer of copper and at least one layer of gold.

While this specification contains many details, these should not be understood as limitations on the scope of what may be claimed, but rather as descriptions of features specific to particular examples. Certain features that are described in this specification or shown in the drawings in the context of separate implementations can also be combined. Conversely, various features that are described or shown in the context of a single implementation can also be implemented in multiple implementations separately or in any suitable sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single product or packaged into multiple products.

A number of embodiments have been described. Nevertheless, it will be understood that various modifications can be made. Accordingly, other embodiments are within the scope of the following claims.

1. An assembly to house a component of a quantum processing unit in a cryogenic environment, the assembly comprising:
a plate configured to reside in thermal contact with a thermalization stage of a cryostat;
a magnetic shielding structure that defines an interior volume to contain a component of a quantum processing unit, the component residing on a circuit board;
a first thermalization pathway that provides thermal contact between the plate and the magnetic shielding structure; and
a second, independent thermalization pathway that provides thermal contact between the plate and the circuit board.

2. The assembly of claim 1, wherein the magnetic shielding structure comprises a plurality of magnetic shielding cans.

3. The assembly of claim 1, wherein the first thermalization pathway comprises a thermalization frame mounted to the magnetic shielding structure and configured to thermalize the magnetic shielding structure to the plate.

4. The assembly of claim 1, wherein the second thermalization pathway comprises a set of interleaved circuit board brackets in thermal contact with the circuit board and configured to thermalize the circuit board to the plate.

5. The assembly of claim 1, wherein:
the thermalization stage is a lowest-temperature thermalization stage in the cryostat; and
the plate, the magnetic shielding structure, and the circuit board are thermalized to the lowest-temperature thermalization stage.

6. The assembly of claim 1, wherein the component of the quantum processing unit resides on a central portion of the circuit board, the circuit board comprises electrical circuitry extending from a first end portion to a second end portion via the central portion of the circuit board, and the electrical circuitry is configured to communicate signals with the component of the quantum processing unit.

7. The assembly of claim 6, wherein the magnetic shielding structure comprises a plurality of magnetic shielding cans, the plurality of magnetic shielding cans comprise slots, the circuit board protrudes through the slots, the first and second end portions of the circuit board reside outside the plurality of magnetic shielding cans, and the central portion of the circuit board reside inside the plurality of magnetic shielding cans.

8. The assembly of claim 7, comprising a sealant material between the circuit board and edges of the slots, wherein the sealant material prevents direct contact between the plurality of magnetic shielding cans and the circuit board.

9. The assembly of claim 6, wherein the component of the quantum processing unit comprises at least a portion of a superconducting quantum circuit, the superconducting quantum circuit comprises at least one of flux bias lines or microwave feedlines communicably coupled to the electrical circuitry of the circuit board.

10. The assembly of claim 1, wherein the circuit board comprises superconducting material.

11. The assembly of claim 1, wherein the plate comprises a first segment and a second, distinct segment, the first thermalization pathway provides thermal contact between the first segment and the magnetic shielding structure, and the second, independent thermalization pathway provides thermal contact between the second segment and the circuit board.

12. The assembly of claim 1, comprising:
an infrared shielding can configured to protect the component of the quantum processing unit on the circuit board from infrared radiation.

13. The assembly of claim 1, wherein the magnetic shielding structure comprises magnetic material, and inner and outer surfaces of the magnetic shielding structure are coated with thermally conductive material.

14. The assembly of claim 13, wherein the magnetic material comprises a nickel iron alloy and the thermal conductive material on the inner and outer surfaces of the magnetic shielding structure comprises at least one layer of copper and at least one layer of gold.

15. The assembly of claim 1, wherein the plate is a first plate comprising a first segment and a second segment, the assembly comprises a second plate comprising a third segment and a fourth segment, the first thermalization pathway provides thermal contact between the second and fourth segments and the magnetic shielding structure, and the second thermalization pathway provides thermal contact between the first and third segments and the circuit board.

16. A method comprising:
positioning a circuit board in an assembly in a cryostat, wherein a component of a quantum processing unit resides on the circuit board, the assembly comprises a magnetic shielding structure, and the circuit board is positioned such that the component is housed within the magnetic shielding structure;
thermalizing the magnetic shielding structure of the assembly to a thermalization stage of the cryostat via a first thermalization pathway defined by the assembly; and
thermalizing the circuit board to the thermalization stage of the cryostat via a second, distinct thermalization pathway defined by the assembly.

17. The method of claim 16, wherein the assembly comprises a plate, the plate is in thermal contact with the thermalization stage of the cryostat, and thermalizing the magnetic shielding structure and the circuit board to the thermalization stage comprises thermalizing the magnetic shielding structure and the circuit board to the plate.

18. The method of claim 17, wherein the first thermalization pathway comprises a thermalization frame mounted to the magnetic shielding structure and configured to thermalize the magnetic shielding structure to the plate.

19. The method of claim 17, wherein the second thermalization pathway comprises a set of interleaved circuit board brackets in thermal contact with the circuit board and configured to thermalize the circuit board to the plate.

20. The method of claim 17, wherein:
the thermalization stage is a lowest-temperature thermalization stage in the cryostat; and
thermalizing the magnetic shielding structure and the circuit board comprises thermalizing the magnetic shielding structure and the circuit board to the lowest-temperature thermalization stage.

21-30. (canceled)
